(19) United States
(12) Patent Application Publication
(10) Pub. No.: US 2024/0331761 A1
(43) Pub. Date: Oct. 3, 2024

(54) N-P BALANCED MULTI-PORT REGISTER FILE WITH COMPLEMENTARY FIELD-EFFECT TRANSISTORS (CFETS)

(71) Applicant: Intel Corporation, Santa Clara, CA (US)

(72) Inventors: Charles Augustine, Portland, OR (US); Amlan Ghosh, Mebane, NC (US); Seenivasan Subramaniam, Hillsboro, OR (US); Patrick Morrow, Portland, OR (US); Muhammad M. Khellah, Tigard, OR (US); Feroze Merchant, Austin, TX (US)

(21) Appl. No.: 18/126,680

(22) Filed: Mar. 27, 2023

(51) Int. Cl. G11C 11/4096; G11C 11/4093; G11C 11/4094

(52) U.S. Cl. CPC G11C 11/4096; G11C 11/4093; G11C 11/4094

(57) ABSTRACT

An apparatus includes a first write bit line (WBL), a first P-channel metal oxide semiconductor (PMOS) transistor including a source coupled to the WBL, a first inverter including an input coupled to a drain of the first PMOS transistor, and a second PMOS transistor including a source coupled to an output of the first inverter. The first PMOS transistor and the second PMOS transistor are disposed in at least one PMOS layer configured between a first metal layer and a second metal layer. The register file circuit further includes a first via connecting a gate of the first PMOS transistor and a gate of the second PMOS transistor in the at least one PMOS layer to the first metal layer.

### TECHNICAL FIELD

Embodiments pertain to improvements in memory architectures, including techniques for improving the die area of an N-P balanced multi-port register file of a memory device.

### BACKGROUND

Demand for memories has been increasing as larger on-die caches are employed in our high-performance processors and this demand is further amplified due to the integration of accelerators (e.g., tile matrix multiply unit (TMUL), advanced vector extensions (AVX), vision processing unit (VPU), etc.) to support new workloads. In addition to six-transistor (6T) static random-access memory (SRAM) devices, multi-ported register files (RFs) also contribute to significant die area especially for graphics processing unit (GPU) execution units and for central processing unit (CPU) instruction and data caches. Similar to 6T SRAM, multi-ported RF also faces scalability issues due to lithography challenges associated with process scaling even though standard logic cells continued to scale across technology generations.

An existing multi-ported register file with one read line and one write line (1R1 W) includes six N-channel metal oxide semiconductor (NMOS) transistors and two P-channel metal oxide semiconductor (PMOS) transistors. An existing multi-ported register file with two read lines and one write line (2R1 W) includes eight NMOS transistors and two PMOS transistors. Both of these designs are highly asymmetric in that they both include NMOS transistor to PMOS transistors in ratios greater than 2:1. This asymmetry makes it difficult to exploit three-dimensional (3D) complementary field-effect transistor (CFET) technology. As a result, register file area scaling is not feasible and larger memory dies are realized.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of a radio architecture including an interface card with a memory device configured according to disclosed techniques, in accordance with some embodiments;

FIG. 2 illustrates a front-end module circuitry for use in the radio architecture of FIG. 1, in accordance with some embodiments;

FIG. 3 illustrates a radio IC circuitry for use in the radio architecture of FIG. 1, in accordance with some embodiments;

FIG. 4 illustrates a baseband processing circuitry for use in the radio architecture of FIG. 1, in accordance with some embodiments;

FIG. 5 illustrates an example computing system with a memory device configured according to disclosed techniques, in accordance with some embodiments;

FIG. 6 illustrates a block diagram of an example processor and/or SoC that may have one or more cores, an integrated memory controller, and a memory device configured according to disclosed techniques, in accordance with some embodiments;

FIG. 7 is a block diagram illustrating both an example in-order pipeline and an example register renaming, out-of-order issue/execution pipeline, in accordance with some embodiments;

FIG. 8 is a block diagram illustrating both an example in-order architecture core and an example register renaming, out-of-order issue/execution architecture core to be included in a processor, in accordance with some embodiments;

FIG. 9 is a block diagram of a three-dimensional (3D) model of a CFET with vertically stacked P-channel metal oxide semiconductor (PMOS) transistors and N-channel metal oxide semiconductor (NMOS) transistors, in accordance with some embodiments;

FIG. 10 is a circuit diagram of an embodiment of a two-read-one-write (2R1 W) register file that benefits from CFET technology area gains, in accordance with some embodiments;

FIG. 11 is a layout diagram of an embodiment of a front side portion of the register file of FIG. 10, in accordance with some embodiments;

FIG. 12 is a layout diagram of an embodiment of a back side portion of the register file of FIG. 10, in accordance with some embodiments;

FIG. 13 is a circuit diagram of an embodiment of an eight-transistor (8T) 2R1 W register file with 4 NMOS and 4 PMOS transistors, in accordance with some embodiments;

FIG. 14 is a layout diagram of an embodiment of a front side portion of the register file of FIG. 13, in accordance with some embodiments;

FIG. 15 is a layout diagram of an embodiment of a back side portion of the register file of FIG. 13, in accordance with some embodiments;

FIG. 16 is a layout diagram of an embodiment of a front side metal layer and a back side metal layer of the register file of FIG. 13, in accordance with some embodiments;

FIG. 17 is a layout diagram of an embodiment of a front side portion of the register file of FIG. 13, in accordance with some embodiments;

FIG. 18 is a layout diagram of an embodiment of front side metal layers of the register file of FIG. 13, in accordance with some embodiments;

FIG. 19 is a layout diagram of an embodiment of a back side portion of the register file of FIG. 13, in accordance with some embodiments;

FIG. 20 is a layout diagram of an embodiment of the back side metal layers of the register file of FIG. 13, in accordance with some embodiments;

FIG. 21 is a reference layout of layers and vias used by the disclosed CFET devices, in accordance with some embodiments;

FIG. 22 is a flow diagram of an example method for configuring a register file, in accordance with some embodiments; and

FIG. 23 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for, those of other embodiments. Embodiments outlined in the claims encompass all available equivalents of those claims.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, materials, insulator thicknesses, and gate(s) configurations, to mention just a few. Moreover, unless specifically referred to as MOS, TFET, CFET, or other, the term transistor can encompass other suitable transistor types, e.g., junction-field-effect transistors, bipolar-junction transistors, metal-semiconductor FETs, and various types of three-dimensional transistors, known today or not yet developed.

The term “channel” refers to a transmission path through which a signal (X(t) in the depicted figure) propagates from a transmitter output to a receiver input. It may include combinations of conductive traces, wireless paths, and/or optical transmission media. For example, it could include combinations of packaging components (e.g., bond wires, solder balls), package traces, sockets, printed-circuit board (PCB) traces, cables (e.g., coaxial, ribbon, twisted pair), waveguides, air (and any other wireless transmission media), optical cable (and other optical transmission components), and so on. It may also include higher-level components for driving, routing, and/or switching signals onto or off of the channel.

As used herein, the term “chip” (or die) refers to a piece of a material, such as a semiconductor material, that includes a circuit such as an integrated circuit or a part of an integrated circuit.

The term memory IP indicates memory intellectual property. The terms memory IP, memory device, memory chip, and memory are interchangeable.

A chipset is an integrated circuit block that has been designed to work with other chipsets to form larger more complex processing modules. In such modules, a system is subdivided into circuit blocks, called “chipsets”, that are often made of reusable IP blocks. They typically are formed on a single semiconductor die but may comprise multiple dies or die components. A benefit of employing chipsets to make a processing module is that they may be formed from different process nodes with different associated strengths, costs, etc. In addition, in many cases, it is easier to make smaller chipsets forming a larger, overall processing system rather than implementing the system on a single die.

The disclosed techniques include configuring a hardware test bench (also referred to as memory timing characterization circuitry) to measure on-chip timing parameters with high resolution for memory IPs (such as setup, hold, clock-to-q time, and cycle time). Such memory timing test-bench can be part of memory built-in self-test (BIST) and can be used to enhance the BIST testing coverage. In some aspects, the disclosed techniques include measuring on-chip timing parameters for sequential elements. However, unlike sequential elements, memory IPs have additional challenges for on-chip timing measurements. These challenges include (a) multiple address, write-data, clock, and data-out inputs/outputs; (b) the physical location of inputs/outputs is not close which adds to measurement error; and (c) complexity due to multiple input switching permutations. The disclosed techniques include a fully configurable synthesizable memory IP timing characterization test bench, featuring distributed regional capture flip-flop circuits (RCFFs) with mesh-based low skew clock, a main capture flip-flop circuit (MCFF) to measure setup difference across RCFFs, multiple data/input delay generators with high-resolution to handle timing permutations, automated relative placement/pre-routing for matched layout and XORed clock delay generators to create multiple edges for measuring read after write delay/cycle time.

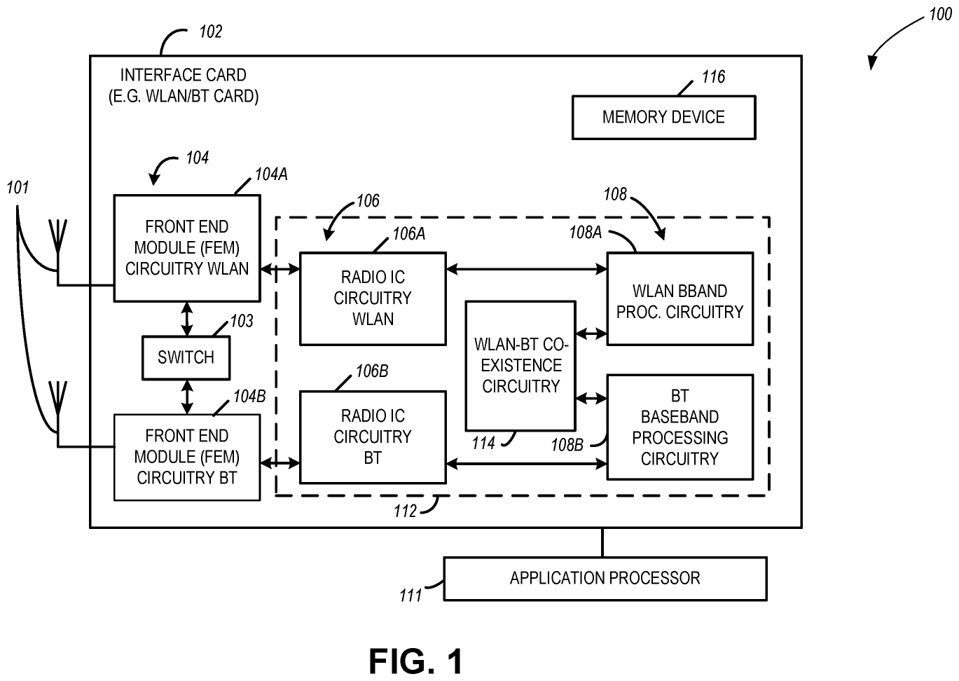

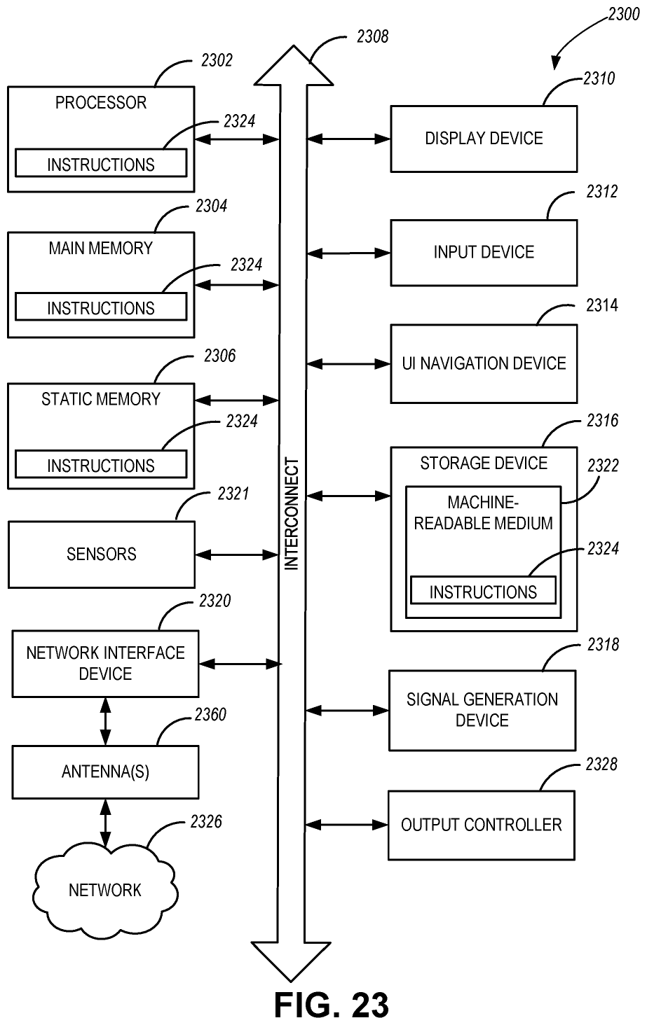

FIG. 1 is a block diagram of a radio architecture 100 including an interface card 102 with a memory device 116, in accordance with some embodiments. The radio architecture 100 may be implemented in a computing device (e.g., machine 2300 in FIG. 23) including user equipment (UE), a base station (e.g., a next-generation Node-B (gNB), enhanced Node-B (eNB)), a smartphone, a personal computer (PC), a laptop, a tablet, or another type of wired or wireless device. The radio architecture 100 may include radio front-end module (FEM) circuitry 104, radio integrated circuit (IC) circuitry 106, memory device 116, and baseband processing circuitry 108 configured as part of the interface card 102. In this regard, radio architecture 100 (as shown in FIG. 1) includes an interface card 102 configured to perform both Wireless Local Area Network (WLAN) functionalities and Bluetooth (BT) functionalities (e.g., as WLAN/BT interface or modem card), although embodiments are not so limited and the disclosed techniques apply to other types of radio architectures with different types of interface cards as well. In this disclosure, “WLAN” and “Wi-Fi” are used interchangeably. Other example types of interface cards which can be used in connection with the disclosed techniques include graphics cards, network cards, SSD cards (such as M.2-based cards), CEM-based cards, etc.

FEM circuitry 104 may include a WLAN or Wi-Fi FEM circuitry 104A and a Bluetooth (BT) FEM circuitry 104B. The WLAN FEM circuitry 104A may include a receive signal path comprising circuitry configured to operate on WLAN RF signals received from one or more antennas 101, to amplify the received signals, and provide the amplified versions of the received signals to the WLAN radio IC circuitry 106A for further processing. The BT FEM circuitry 104B may include a receive signal path which may include circuitry configured to operate on BT RF signals received from the one or more antennas 101, to amplify the received signals, and provide the amplified versions of the received signals to the BT radio IC circuitry 106B for further processing. The WLAN FEM circuitry 104A may also include a transmit signal path which may include circuitry configured to amplify WLAN signals provided by the radio IC circuitry 106A for wireless transmission by the one or more antennas 101. Besides, the BT FEM circuitry 104B may also include a transmit signal path which may include circuitry configured to amplify BT signals provided by the radio IC circuitry 106B for wireless transmission by the one or more antennas. In the embodiment of FIG. 1, although WLAN FEM circuitry 104A and BT FEM circuitry 104B are shown as being distinct from one another, embodiments are not so limited and include within their scope the use of a FEM (not shown) that includes a transmit path and/or a receive path for both WLAN and BT signals, or the use of one or more FEM circuitries where at least some of the FEM circuitries share transmit and/or receive signal paths for both WLAN and BT signals.

Radio IC circuitry 106 as shown may include WLAN radio IC circuitry 106A and BT radio IC circuitry 106B. The WLAN radio IC circuitry 106A may include a receive signal path which may include circuitry to down-convert WLAN RF signals received from the WLAN FEM circuitry 104A and provide baseband signals to WLAN baseband processing circuitry 108A. The BT radio IC circuitry 106B may, in turn, include a receive signal path which may include circuitry to down-convert BT RF signals received from the BT FEM circuitry 104B and provide baseband signals to BT baseband processing circuitry 108B. The WLAN radio IC circuitry 106A may also include a transmit signal path which may include circuitry to up-convert WLAN baseband signals provided by the WLAN baseband processing circuitry 108A and provide WLAN RF output signals to the WLAN FEM circuitry 104A for subsequent wireless transmission by the one or more antennas 101. The BT radio IC circuitry 106B may also include a transmit signal path which may include circuitry to up-convert BT baseband signals provided by the BT baseband processing circuitry 108B and provide BT RF output signals to the BT FEM circuitry 104B for subsequent wireless transmission by the one or more antennas 101. In the embodiment of FIG. 1, although radio IC circuitries 106A and 106B are shown as being distinct from one another, embodiments are not so limited and include within their scope the use of a radio IC circuitry (not shown) that includes a transmit signal path and/or a receive signal path for both WLAN and BT signals, or the use of one or more radio IC circuitries where at least some of the radio IC circuitries share transmit and/or receive signal paths for both WLAN and BT signals.

Baseband processing circuitry 108 may include a WLAN baseband processing circuitry 108A and a BT baseband processing circuitry 108B. The WLAN baseband processing circuitry 108A may include a memory, such as, for example, a set of RAM arrays in a Fast Fourier Transform (FFT) or Inverse Fast Fourier Transform (IFFT) block (not shown) of the WLAN baseband processing circuitry 108A. Each of the WLAN baseband processing circuitry 108A and the BT baseband processing circuitry 108B may further include one or more processors and control logic to process the signals received from the corresponding WLAN or BT receive signal path of the radio IC circuitry 106, and to also generate corresponding WLAN or BT baseband signals for the transmit signal path of the radio IC circuitry 106. Each of the baseband processing circuitries 108A and 108B may further include a physical layer (PHY) and medium access control layer (MAC) circuitry and may further interface with a host processor (e.g., the application processor 111) in a host system (e.g., a host SoC) for generation and processing of the baseband signals and for controlling operations of the radio IC circuitry 106 (including controlling the operation of the memory device 116).

Referring still to FIG. 1, according to the shown embodiment, WLAN-BT coexistence circuitry 114 may include logic providing an interface between the WLAN baseband processing circuitry 108A and the BT baseband processing circuitry 108B to enable use cases requiring WLAN and BT coexistence. In addition, a switch 103 may be provided between the WLAN FEM circuitry 104A and the BT FEM circuitry 104B to allow switching between the WLAN and BT radios according to application needs. In addition, although the one or more antennas 101 are depicted as being respectively connected to the WLAN FEM circuitry 104A and the BT FEM circuitry 104B, embodiments include within their scope the sharing of the one or more antennas 101 as between the WLAN and BT FEMs, or the provision of more than one antenna connected to each of FEM circuitries 104A or 104B.

In some embodiments, the front-end module circuitry 104, the radio IC circuitry 106, and the baseband processing circuitry 108 may be provided on a single radio card, such as the interface card 102. In some other embodiments, the one or more antennas 101, the FEM circuitry 104, and the radio IC circuitry 106 may be provided on a single radio card. In some other embodiments, the radio IC circuitry 106 and the baseband processing circuitry 108 may be provided on a single chip or IC, such as IC 112.

In some embodiments, the interface card 102 can be configured as a wireless radio card, such as a WLAN radio card configured for wireless communications (e.g., WiGig communications in the 60 GHz range or mmW communications in the 24.24 GHz-52.6 GHz range), although the scope of the embodiments is not limited in this respect. In some of these embodiments, the radio architecture 100 may be configured to receive and transmit orthogonal frequency division multiplexed (OFDM) or orthogonal frequency division multiple access (OFDMA) communication signals over a multicarrier communication channel. The OFDM or OFDMA signals may comprise a plurality of orthogonal subcarriers.

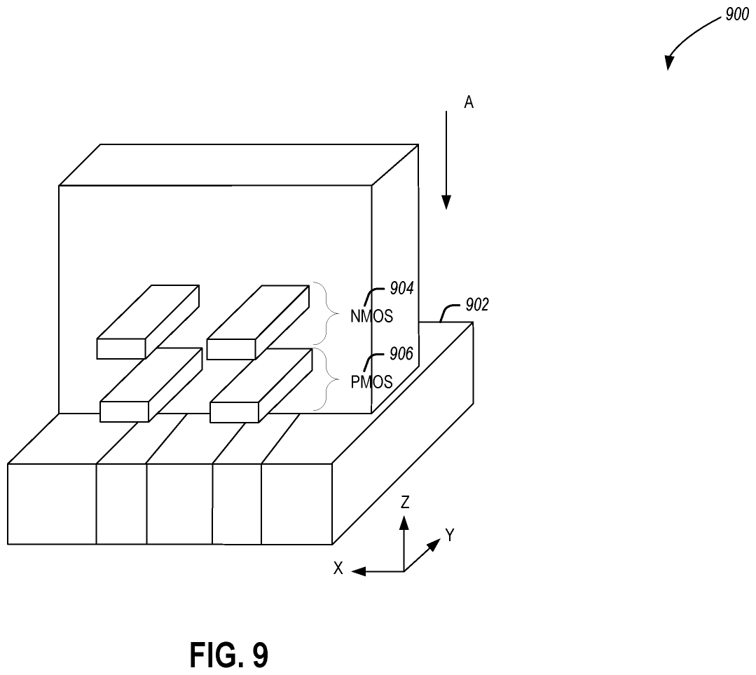

In some embodiments, the interface card 102 may include one or more memory devices such as memory device 116. Memory device 116 can be configured based on the disclosed techniques. In this regard, memory device 116 can be the same as, or include, one or more of the memory devices discussed in connection with FIGS. 9-23. Configuring (including testing) the memory device 116 (or any of the memory devices discussed herein) can be based on one or more of the techniques discussed in connection with FIGS. 9-23.

In some of these multicarrier embodiments, radio architecture 100 may be a part of a Wi-Fi communication station (STA) such as a wireless access point (AP), a base station, or a mobile device including a Wi-Fi-enabled device. In some of these embodiments, radio architecture 100 may be configured to transmit and receive signals in accordance with specific communication standards and/or protocols, such as any of the Institute of Electrical and Electronics Engineers (IEEE) standards including, 802.11n-2009, IEEE 802.11-2012, 802.11n-2009, 802.11ac, IEEE 802.11-2016, 802.11ad, and/or 802.11ax standards and/or proposed specifications for WLANs, although the scope of embodiments is not limited in this respect and operations using other wireless standards can also be configured. Radio architecture 100 may also be suitable to transmit and/or receive communications in accordance with other techniques and standards, including a 3rd Generation Partnership Project (3GPP) standard, including a communication standard used in connection with 5G or new radio (NR) communications.

In some embodiments, the radio architecture 100 may be configured for high-efficiency (HE) Wi-Fi communications in accordance with the IEEE 802.11ax standard or another standard associated with wireless communications. In these embodiments, the radio architecture 100 may be configured to communicate in accordance with an OFDMA technique, although the scope of the embodiments is not limited in this respect.

In some other embodiments, the radio architecture 100 may be configured to transmit and receive signals transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

In some embodiments, as further shown in FIG. 1, the BT baseband processing circuitry 108B may be compliant with a Bluetooth (BT) connectivity standard such as Bluetooth, Bluetooth 4.0 or Bluetooth 5.0, or any other iteration of the Bluetooth Standard. In embodiments that include BT functionality as shown for example in FIG. 1, the radio architecture 100 may be configured to establish a BT synchronous connection-oriented (SCO) link and or a BT low energy (BT LE) link. In some of the embodiments that include functionality, the radio architecture 100 may be configured to establish an extended SCO (eSCO) link for BT communications, although the scope of the embodiments is not limited in this respect. In some of these embodiments that include a BT functionality, the radio architecture may be configured to engage in a BT Asynchronous Connection-Less (ACL) communications, although the scope of the embodiments is not limited in this respect. In some embodiments, as shown in FIG. 1, the functions of a BT radio card and WLAN radio card may be combined on a single wireless radio card, such as the interface card 102, although embodiments are not so limited, and include within their scope discrete WLAN and BT radio cards

In some embodiments, the radio architecture 100 may include other radio cards, such as a cellular radio card configured for cellular/wireless communications (e.g., 3GPP such as LTE, LTE-Advanced, WiGig, or 5G communications including mmW communications), which may be implemented together with (or as part of) the interface card 102.

In some IEEE 802.11 embodiments, the radio architecture 100 may be configured for communication over various channel bandwidths including bandwidths having center frequencies of about 900 MHZ, 2.4 GHz, 5 GHZ, and bandwidths of about 1 MHz, 2 MHZ, 2.5 MHz, 4 MHZ, 5 MHZ, 8 MHz, 10 MHz, 16 MHz, 20 MHz, 40 MHz, 80 MHz (with contiguous bandwidths) or 80+80 MHz (160 MHz) (with non-contiguous bandwidths). In some embodiments, a 320 MHz channel bandwidth may be used. The scope of the embodiments is not limited with respect to the above center frequencies, however.

In some embodiments, memory device 116 is configured as cache memory, including array and queues used in high-performance microprocessor CPU/GPU designs. Other use cases of the disclosed memory devices can be configured as well.

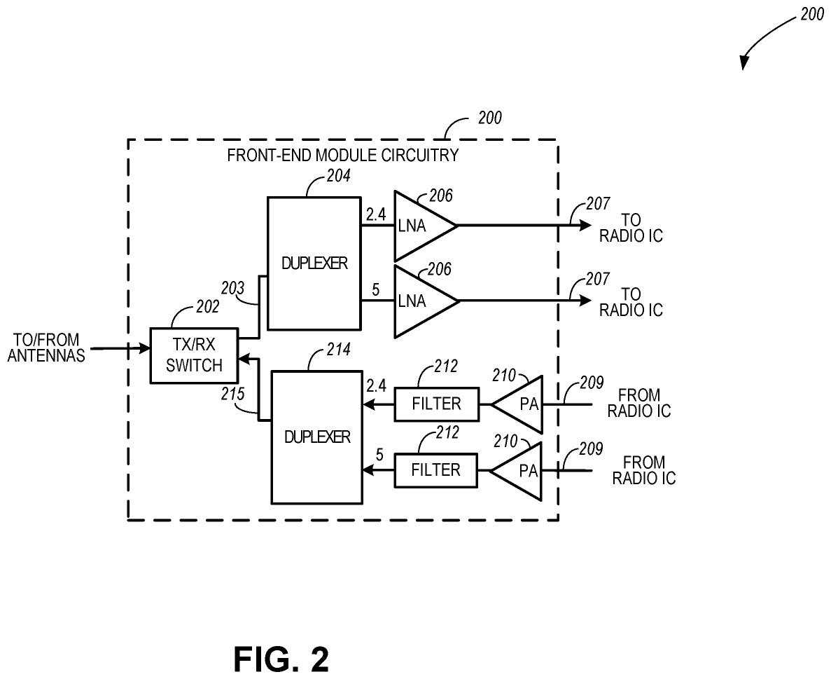

FIG. 2 illustrates FEM circuitry 200 in accordance with some embodiments. The FEM circuitry 200 is one example of circuitry that may be suitable for use as the WLAN and/or BT FEM circuitry 104A/104B (FIG. 1), although other circuitry configurations may also be suitable.

In some embodiments, the FEM circuitry 200 may include a TX/RX switch 202 to switch between transmit (TX) mode and receive (RX) mode operation. In some aspects, a diplexer may be used in place of a TX/RX switch. The FEM circuitry 200 may include a receive signal path and a transmit signal path. The receive signal path of the FEM circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the FEM circuitry 200 may include a power amplifier (PA) to amplify input RF signals 209 (e.g., provided by the radio IC circuitry 106), and one or more filters 212, such as band-pass filters (BPFs), low-pass filters (LPFs) or other types of filters, to generate RF signals 215 for subsequent transmission (e.g., by the one or more antennas 101 (FIG. 1)).

In some dual-mode embodiments for Wi-Fi communication, the FEM circuitry 200 may be configured to operate in, e.g., either the 2.4 GHz frequency spectrum or the 5 GHz frequency spectrum. In these embodiments, the receive signal path of the FEM circuitry 200 may include a receive signal path duplexer 204 to separate the signals from each spectrum as well as provide a separate LNA 206 for each spectrum as shown. In these embodiments, the transmit signal path of the FEM circuitry 200 may also include a power amplifier (PA) 210 and one or more filters 212, such as a BPF, an LPF, or another type of filter for each frequency spectrum, and a transmit signal path duplexer 214 to provide the signals of one of the different spectrums onto a single transmit path for subsequent transmission by the one or more antennas 101 (FIG. 1). In some embodiments, BT communications may utilize the 2.4 GHz signal path and may utilize the same FEM circuitry 200 as the one used for WLAN communications.

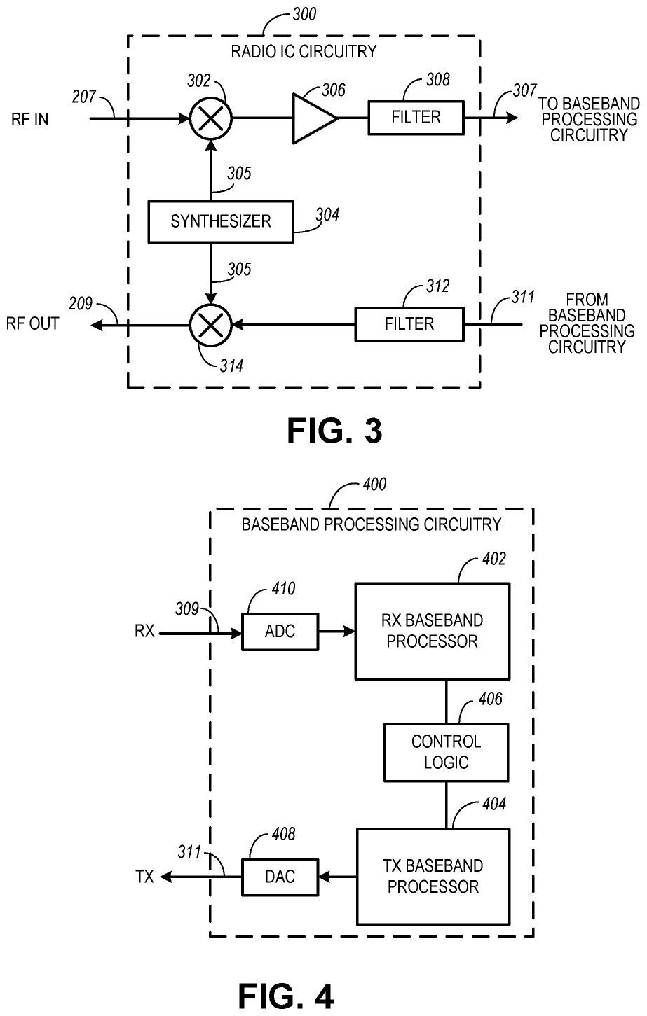

FIG. 3 illustrates radio IC circuitry 300 in accordance with some embodiments. The radio IC circuitry 300 is one example of circuitry that may be suitable for use as the WLAN or BT radio IC circuitry 106A/106B (FIG. 1), although other circuitry configurations may also be suitable.

In some embodiments, the radio IC circuitry 300 may include a receive signal path and a transmit signal path. The receive signal path of the radio IC circuitry 300 may include mixer circuitry 302, such as, for example, down-conversion mixer circuitry, amplifier circuitry 306, and filter circuitry 308. The transmit signal path of the radio IC circuitry 300 may include at least filter circuitry 312 and mixer circuitry 314, such as up-conversion mixer circuitry. Radio IC circuitry 300 may also include synthesizer circuitry 304 for synthesizing a frequency 305 for use by the mixer circuitry 302 and the mixer circuitry 314. The mixer circuitry 302 and/or 314 may each, according to some embodiments, be configured to provide direct conversion functionality. The latter type of circuitry presents a much simpler architecture as compared with standard super-heterodyne mixer circuitries, and any flicker noise brought about by the same may be alleviated for example through the use of OFDM modulation. FIG. 3 illustrates only a simplified version of a radio IC circuitry and may include, although not shown, embodiments where each of the depicted circuitries may include more than one component. For instance, mixer circuitry 302 and/or 314 may each include one or more mixers, and filter circuitries 308 and/or 312 may each include one or more filters, such as one or more BPFs and/or LPFs according to application needs. For example, when mixer circuitries are of the direct-conversion type, they may each include two or more mixers.

In some embodiments, mixer circuitry 302 may be configured to down-convert RF signals 207 received from the FEM circuitry 104 (FIG. 1) based on the synthesized frequency 305 provided by the synthesizer circuitry 304. The amplifier circuitry 306 may be configured to amplify the down-converted signals and the filter circuitry 308 may include an LPF configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 311 based on the synthesized frequency 305 provided by the synthesizer circuitry 304 to generate RF output signals 209 for the FEM circuitry 104. The baseband signals 311 may be provided by the baseband processing circuitry 108 and may be filtered by filter circuitry 312. The filter circuitry 312 may include an LPF or a BPF, although the scope of the embodiments is not limited in this respect.

In some embodiments, the mixer circuitry 302 and the mixer circuitry 314 may each include two or more mixers and may be arranged for quadrature down-conversion and/or up-conversion respectively with the help of the synthesizer circuitry 304. In some embodiments, the mixer circuitry 302 and the mixer circuitry 314 may each include two or more mixers each configured for image rejection (e.g., Hartley image rejection). In some embodiments, the mixer circuitry 302 and the mixer circuitry 314 may be arranged for direct down-conversion and/or direct up-conversion, respectively. In some embodiments, the mixer circuitry 302 and the mixer circuitry 314 may be configured for super-heterodyne operation, although this is not a requirement.

Mixer circuitry 302 may comprise, according to one embodiment: quadrature passive mixers (e.g., for the in-phase (I) and quadrature-phase (Q) paths). In such an embodiment, RF input signal 207 from FIG. 2 may be down-converted to provide I and Q baseband output signals to be sent to the baseband processor.

Quadrature passive mixers may be driven by zero and ninety-degree time-varying LO switching signals provided by a quadrature circuitry which may be configured to receive a LO frequency (fLO) from a local oscillator or a synthesizer, such as LO frequency 305 of synthesizer circuitry 304 (FIG. 3). In some embodiments, the LO frequency may be the carrier frequency, while in other embodiments, the LO frequency may be a fraction of the carrier frequency (e.g., one-half the carrier frequency, one-third the carrier frequency). In some embodiments, the zero and ninety-degree time-varying switching signals may be generated by the synthesizer, although the scope of the embodiments is not limited in this respect.

In some embodiments, the LO signals may differ in the duty cycle (the percentage of one period in which the LO signal is high) and/or offset (the difference between the start points of the period). In some embodiments, the LO signals may have a 25% duty cycle and a 50% offset. In some embodiments, each branch of the mixer circuitry (e.g., the in-phase (I) and quadrature-phase (Q) path) may operate at a 25% duty cycle, which may result in a significant reduction in power consumption.

The RF input signal 207 (FIG. 2) may comprise a balanced signal, although the scope of the embodiments is not limited in this respect. The I and Q baseband output signals may be provided to the low-noise amplifier, such as amplifier circuitry 306 (FIG. 3) or filter circuitry 308 (FIG. 3).

In some embodiments, the output baseband signals 307 and the input baseband signals 311 may be analog, although the scope of the embodiments is not limited in this respect. In some alternate embodiments, the output baseband signals 307 and the input baseband signals 311 may be digital. In these alternate embodiments, the radio IC circuitry may include an analog-to-digital converter (ADC) and digital-to-analog converter (DAC) circuitry.

In some dual-mode embodiments, a separate radio IC circuitry may be provided for processing signals for each spectrum, or for other spectrums not mentioned here, although the scope of the embodiments is not limited in this respect.

In some embodiments, the synthesizer circuitry 304 may be a fractional-N synthesizer or a fractional N/N+1 synthesizer, although the scope of the embodiments is not limited in this respect as other types of frequency synthesizers may be suitable. In some embodiments, the synthesizer circuitry 304 may be a delta-sigma synthesizer, a frequency multiplier, or a synthesizer comprising a phase-locked loop with a frequency divider. According to some embodiments, the synthesizer circuitry 304 may include a digital frequency synthesizer circuitry. An advantage of using a digital synthesizer circuitry is that, although it may still include some analog components, its footprint may be scaled down much more than the footprint of an analog synthesizer circuitry. In some embodiments, frequency input into synthesizer circuitry 304 may be provided by a voltage-controlled oscillator (VCO), although that is not a requirement. A divider control input may further be provided by either the baseband processing circuitry 108 (FIG. 1) or the host processor 111 (FIG. 1) depending on the desired output frequency 305. In some embodiments, a divider control input (e.g., N) may be determined from a look-up table (e.g., within a Wi-Fi card) based on a channel number and a channel center frequency as determined or indicated by the host processor 111.

In some embodiments, synthesizer circuitry 304 may be configured to generate a carrier frequency as the output frequency 305, while in other embodiments, the output frequency 305 may be a fraction of the carrier frequency (e.g., one-half of the carrier frequency, one-third of the carrier frequency). In some embodiments, the output frequency 305 may be an LO frequency (fLO).

FIG. 4 illustrates a baseband processing circuitry 400 for use in the radio architecture of FIG. 1, in accordance with some embodiments. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 309 provided by the radio IC circuitry 106 (FIG. 1) and a transmit baseband processor (TX BBP) 404 for generating transmit baseband signals 311 for the radio IC circuitry 106. The baseband processing circuitry 400 may also include control logic 406 for coordinating the operations of the baseband processing circuitry 400.

In some embodiments (e.g., when analog baseband signals are exchanged between the baseband processing circuitry 400 and the radio IC circuitry 106), the baseband processing circuitry 400 may include an analog-to-digital converter (ADC) 410 to convert analog baseband signals 309 received from the radio IC circuitry 106 to digital baseband signals for processing by the RX BBP 402. In these embodiments, the baseband processing circuitry 400 may also include a digital-to-analog converter (DAC) 408 to convert digital baseband signals from the TX BBP 404 to analog baseband signals 311.

In some embodiments that communicate OFDM signals or OFDMA signals, such as through the WLAN baseband processing circuitry 108A, the TX BBP 404 may be configured to generate OFDM or OFDMA signals as appropriate for transmission by performing an inverse fast Fourier transform (IFFT). The RX BBP 402 may be configured to process received OFDM signals or OFDMA signals by performing an FFT. In some embodiments, the RX BBP 402 may be configured to detect the presence of an OFDM signal or OFDMA signal by performing an autocorrelation, to detect a preamble, such as a short preamble, and performing a cross-correlation, to detect a long preamble. The preambles may be part of a predetermined frame structure for Wi-Fi communication.

Referring back to FIG. 1, in some embodiments, the one or more antennas 101 (FIG. 1) may each comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result. The one or more antennas 101 may each include a set of phased-array antennas, although embodiments are not so limited.

Although the radio architecture 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application-specific integrated circuits (ASICs), radio-frequency integrated circuits (RFICs), and combinations of various hardware and logic circuitry for performing at least the functions described herein. In some embodiments, the functional elements may refer to one or more processes operating on one or more processing elements.

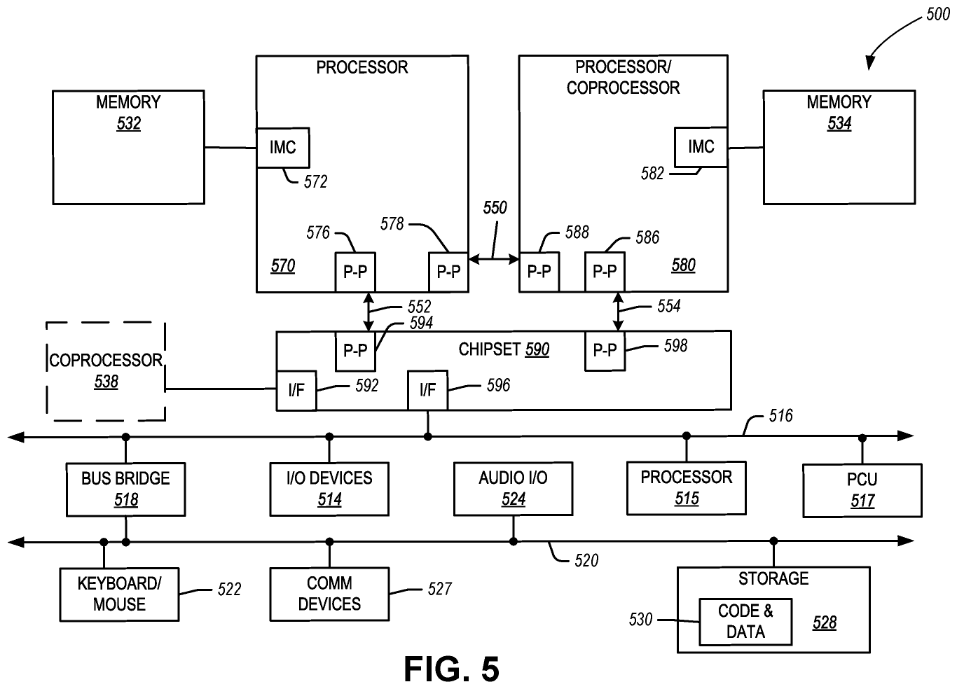

In some aspects (e.g., as discussed in connection with FIGS. 5-8), the disclosed techniques include configuring multi-port, process technology scaling-friendly, balanced P/N 8T bitcells with fully utilized diffusion areas.

FIG. 5 illustrates an example computing system with a memory device configured according to disclosed techniques, in accordance with some embodiments. Multiprocessor system 500 is interfaced and includes a plurality of processors including a first processor 570 and a second processor 580 coupled via an interface 550 such as a point-to-point (P-P) interconnect, a fabric, and/or bus. In some examples, the first processor 570, and the second processor 580 are homogeneous. In some examples, the first processor 570 and the second processor 580 are heterogeneous. Though the example system 500 is shown to have two processors, the system may have three or more processors or may be a single-processor system. In some examples, the computing system is implemented, wholly or partially, with a system on a chip (SoC) or a multi-chip (or multi-chipset) module, in the same or different package combinations.

Processors 570 and 580 are shown including integrated memory controller (IMC) circuitry 572 and 582, respectively. Processor 570 also includes interface circuits 576 and 578, along with core sets. Similarly, the second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570 and 580 may exchange information via interface 550 using interface circuits 578 and 588. IMC circuitry 572 and 582 couple the processors 570 and 580 to respective memories, namely a memory 532 and a memory 534, which may be portions of main memory locally attached to the respective processors. Configuring (including testing) the memory 534 can be based on one or more of the techniques discussed in connection with FIGS. 9-24.

Processors 570 and 580 may each exchange information with a network interface (NW I/F) 590 via individual interfaces 552 and 554 using interface circuits 576, 594, 586, and 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general-purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via the interface circuit 596. In some examples, the first interface 516 may be an interface such as a Peripheral Component Interconnect (PCI) interconnect, a PCI Express interconnect, or another I/O interconnect. In some examples, the first interface 516 is coupled to a power control unit (PCU) 517, which may include circuitry, software, and/or firmware to perform power management operations concerning the processors 570 and 580, and/or coprocessor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints), and/or the power management may be performed responsive to external sources (such as a platform or power management source or system software).

PCU 517 is illustrated as being present as logic separate from processor 570 and/or processor 580. In other aspects, PCU 517 may execute on a given one or more cores (not shown) of processor 570 or 580. In some aspects, PCU 517 may be implemented as a microcontroller (dedicated or general-purpose) or other control logic configured to execute its dedicated power management code, sometimes referred to as P-code. In yet other aspects, power management operations to be performed by PCU 517 may be implemented externally to a processor, such as by way of a separate power management integrated circuit (PMIC) or another component external to the processor. In yet other embodiments, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks, and/or in other parts of the overall system.

Various I/O devices 514 may be coupled to the first interface 516, along with a bus bridge 518 which couples the first interface 516 to a second interface 520. In some examples, one or more additional processor(s) 515, such as coprocessors, high throughput many integrated cores (MIC) processors, GPGPUs, accelerators (such as graphics accelerators or digital signal processing (DSP) units), field programmable gate arrays (FPGAs), or any other processor, are coupled to the first interface 516. In some examples, the second interface 520 may be a low pin count (LPC) interface. Various devices may be coupled to the second interface 520 including, for example, a keyboard and/or mouse 522, communication devices 527, and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to the second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general-purpose in-order core intended for general-purpose computing; 2) a high-performance general-purpose out-of-order core intended for general-purpose computing; and 3) a special purpose core intended primarily for graphics and/or scientific (throughput) computing. Implementations of different processors may include: 1) a CPU including one or more general-purpose in-order cores intended for general-purpose computing and/or one or more general-purpose out-of-order cores intended for general-purpose computing; and 2) a coprocessor including one or more special-purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above-described coprocessor, and additional functionality. Example core architectures are described next, followed by descriptions of example processors and computer architectures.

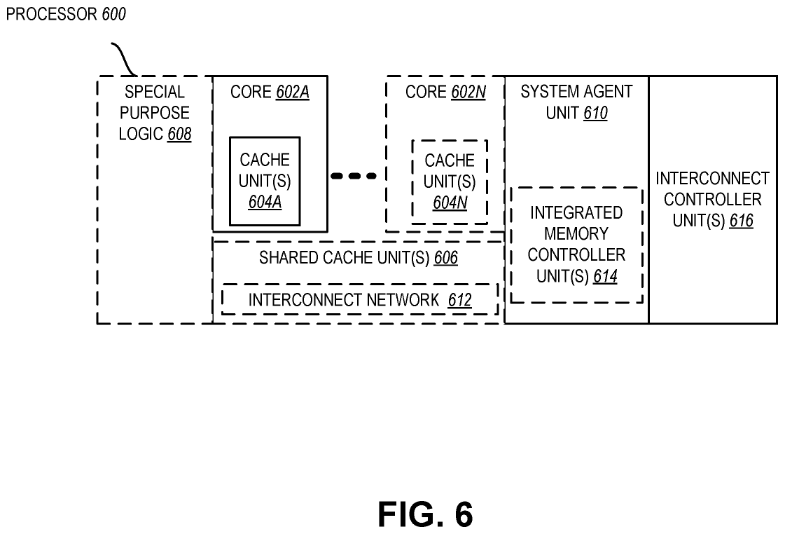

FIG. 6 illustrates a block diagram of an example processor and/or SoC 600 that may have one or more cores, an integrated memory controller, and a memory device configured according to disclosed techniques, in accordance with some embodiments. The solid lined boxes illustrate a processor 600 with a single core 602A, system agent unit circuitry 610, and a set of one or more interface controller unit(s) circuitry 616, while the optional addition of the dashed lined boxes illustrates an alternative processor 600 with multiple cores 602A-602N, a set of one or more integrated memory controller unit(s) circuitry 614 in the system agent unit circuitry 610, and special purpose logic 608, as well as a set of one or more interface controller units circuitry 616. Note that the processor 600 may be one of the processors 570 or 580, or coprocessor 538 or 515 of FIG. 5.

Thus, different implementations of the processor 600 may include 1) a CPU with the special purpose logic 608 being integrated graphics and/or scientific (throughput) logic (which may include one or more cores, not shown), and the cores 602A-602N being one or more general purpose cores (e.g., general purpose in-order cores, general purpose out-of-order cores, or a combination of the two); 2) a coprocessor with the cores 602A-602N being a large number of special purpose cores intended primarily for graphics and/or scientific (throughput); and 3) a coprocessor with the cores 602A-602N being a large number of general purpose in-order cores. Thus, the processor 600 may be a general-purpose processor, coprocessor, or special-purpose processor, such as, for example, a network or communication processor, compression engine, graphics processor, GPGPU (general purpose graphics processing unit), a high throughput many integrated cores (MIC) coprocessor (including 30 or more cores), embedded processor, or the like. The processor may be implemented on one or more chips. The processor 600 may be a part of and/or may be implemented on one or more substrates using any of several process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604A-604N within the cores 602A-602N, a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602A-602N. In some examples, interface controller units circuitry 616 couples the cores 602 to one or more other devices such as one or more I/O devices, storage, one or more communication devices (e.g., wireless networking, wired networking, etc.), etc.

In some examples, one or more of the cores 602A-602N are capable of multi-threading. The system agent unit circuitry 610 includes those components coordinating and operating cores 602A-602N. The system agent unit circuitry 610 may include, for example, power control unit (PCU) circuitry and/or display unit circuitry (not shown). The PCU may be or may include logic and components needed for regulating the power state of the cores 602A-602N and/or the special purpose logic 608 (e.g., integrated graphics logic). The display unit circuitry is for driving one or more externally connected displays.

The cores 602A-602N may be homogenous in terms of instruction set architecture (ISA). Alternatively, the cores 602A-602N may be heterogeneous in terms of ISA; that is, a subset of the cores 602A-602N may be capable of executing an ISA, while other cores may be capable of executing only a subset of that ISA or another ISA.

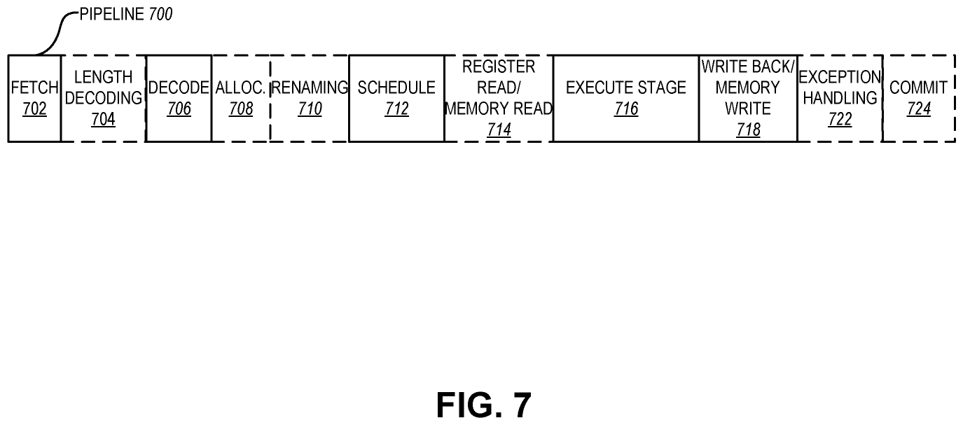

FIG. 7 is a block diagram illustrating both an example in-order pipeline 700 and an example register renaming, out-of-order issue/execution pipeline in accordance with some embodiments;

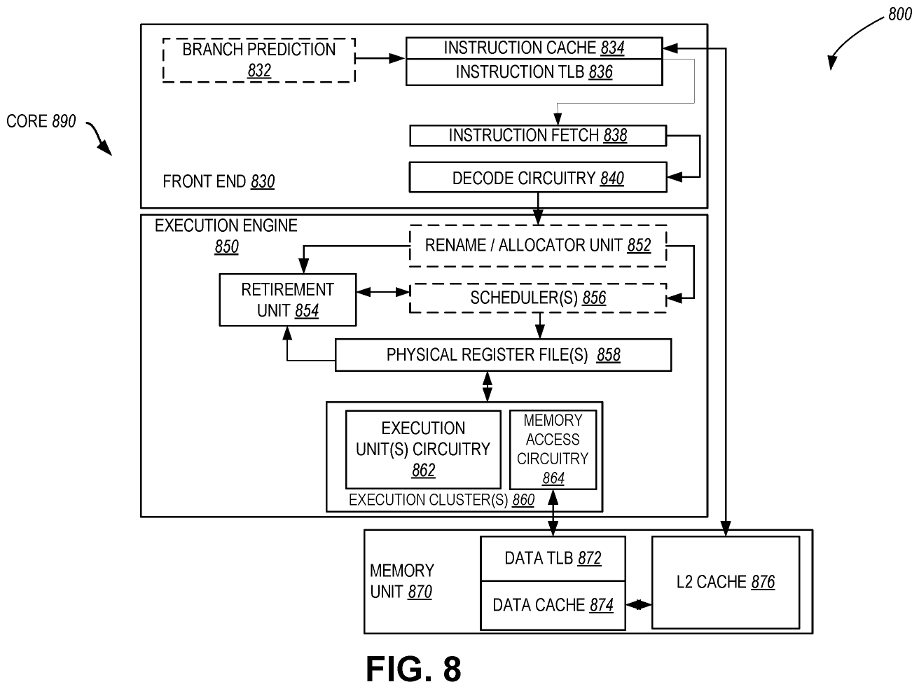

FIG. 8 is a block diagram 800 illustrating both an example in-order architecture core and an example register renaming, out-of-order issue/execution architecture core to be included in a processor in accordance with some embodiments;

The solid lined boxes in FIGS. 7-8 illustrate the in-order pipeline and in-order core, while the optional addition of the dashed lined boxes illustrates the register renaming, out-of-order issue/execution pipeline, and core. Given that the in-order aspect is a subset of the out-of-order aspect, the out-of-order aspect will be described.

In FIG. 7, a processor pipeline 700 includes a fetch stage 702, an optional length decoding stage 704, a decode stage 706, an optional allocation (Alloc) stage 708, an optional renaming stage 710, a schedule (also known as a dispatch or issue) stage 712, an optional register read/memory read stage 714, an execute stage 716, a write-back/memory write stage 718, an optional exception-handling stage 722, and an optional commit stage 724. One or more operations can be performed in each of these processor pipeline stages. For example, during the fetch stage 702, one or more instructions are fetched from instruction memory, and during the decode stage 706, the one or more fetched instructions may be decoded, addresses (e.g., load store unit (LSU) addresses) using forwarded register ports may be generated, and branch forwarding (e.g., immediate offset or a link register (LR)) may be performed. In one example, the decode stage 706 and the register read/memory read stage 714 may be combined into one pipeline stage. In one example, during the execute stage 716, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 8 may implement the pipeline 700 as follows: 1) the instruction fetch circuitry 838 performs the fetch and length decoding stages 702 and 704; 2) the decode circuitry 840 performs the decode stage 706; 3) the rename/allocator unit circuitry 852 performs the allocation stage 708 and renaming stage 710; 4) the scheduler(s) circuitry 856 performs the schedule stage 712; 5) the physical register file(s) circuitry 858 and the memory unit circuitry 870 perform the register read/memory read stage 714; the execution cluster(s) 860 perform the execute stage 716; 6) the memory unit circuitry 870 and the physical register file(s) circuitry 858 perform the write back/memory write stage 718; 7) various circuitry may be involved in the exception handling stage 722; and 8) the retirement unit circuitry 854 and the physical register file(s) circuitry 858 perform the commit stage 724.

FIG. 8 shows a processor core 890 including front-end unit circuitry 830 coupled to execution engine unit circuitry 850, and both are coupled to memory unit circuitry 870. The core 890 may be a reduced instruction set architecture computing (RISC) core, a complex instruction set architecture computing (CISC) core, a very long instruction word (VLIW) core, or a hybrid or alternative core type. As yet another option, the core 890 may be a special-purpose core, such as, for example, a network or communication core, compression engine, coprocessor core, general-purpose computing graphics processing unit (GPGPU) core, graphics core, or the like.

The front-end unit circuitry 830 may include branch prediction circuitry 832 coupled to instruction cache circuitry 834, which is coupled to an instruction translation lookaside buffer (TLB) 836, which is coupled to an instruction fetch circuitry 838, which is coupled to decode circuitry 840. In one example, the instruction cache circuitry 834 is included in the memory unit circuitry 870 rather than the front-end circuitry 830. The decode circuitry 840 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 840 may further include address generation unit (AGU, not shown) circuitry. In one example, the AGU generates an LSU address using forwarded register ports, and may further perform branch forwarding (e.g., immediate offset branch forwarding, LR register branch forwarding, etc.). The decode circuitry 840 may be implemented using different mechanisms. Examples of suitable mechanisms include but are not limited to, look-up tables, hardware implementations, programmable logic arrays (PLAs), microcode read-only memories (ROMs), etc. In one example, the core 890 includes a microcode ROM (not shown) or another medium that stores microcode for certain macroinstructions (e.g., in decode circuitry 840 or otherwise within the front-end circuitry 830). In one example, the decode circuitry 840 includes a micro-operation (micro-op) or operation cache (not shown) to hold/cache decoded operations, micro-tags, or micro-operations generated during the decode or other stages of the processor pipeline 700. The decode circuitry 840 may be coupled to rename/allocator unit circuitry 852 in the execution engine circuitry 850.

The execution engine circuitry 850 includes the rename/allocator unit circuitry 852 coupled to retirement unit circuitry 854 and a set of one or more scheduler(s) circuitry 856. The scheduler(s) circuitry 856 represents any number of different schedulers, including reservations stations, central instruction window, etc. In some examples, the scheduler(s) circuitry 856 can include arithmetic logic unit (ALU) scheduler/scheduling circuitry, ALU queues, address generation unit (AGU) scheduler/scheduling circuitry, AGU queues, etc. The scheduler(s) circuitry 856 is coupled to the physical register file(s) circuitry 858. Each of the physical register file(s) circuitry 858 represents one or more physical register files, different ones of which store one or more different data types, such as scalar integer, scalar floating-point, packed integer, packed floating point, vector integer, vector floating-point, status (e.g., an instruction pointer that is the address of the next instruction to be executed), etc. In one example, the physical register file(s) circuitry 858 includes vector registers unit circuitry, write mask registers unit circuitry, and scalar register unit circuitry. These register units may provide architectural vector registers, vector mask registers, general-purpose registers, etc. The physical register file(s) circuitry 858 is coupled to the retirement unit circuitry 854 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register map and a pool of registers; etc.). The retirement unit circuitry 854 and the physical register file(s) circuitry 858 are coupled to the execution cluster(s) 860. The execution cluster(s) 860 includes a set of one or more execution unit(s) circuitry 862 and a set of one or more memory access circuitry 864. The execution unit(s) circuitry 862 may perform various arithmetic, logic, floating-point, or other types of operations (e.g., shifts, addition, subtraction, multiplication) and on various types of data (e.g., scalar integer, scalar floating-point, packed integer, packed floating point, vector integer, vector floating-point). While some examples may include several execution units or execution unit circuitry dedicated to specific functions or sets of functions, other examples may include only one execution unit circuitry or multiple execution units/execution unit circuitry that perform all functions. The scheduler(s) circuitry 856, physical register file(s) circuitry 858, and execution cluster(s) 860 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each has their scheduler circuitry, physical register file(s) circuitry, and/or execution cluster—and in the case of a separate memory access pipeline, certain examples are implemented in which only the execution cluster of this pipeline has the memory access unit(s) circuitry 864). It should also be understood that where separate pipelines are used, one or more of these pipelines may be out-of-order issue/execution and the rest in-order.

In some examples, the execution engine unit circuitry 850 may perform load store unit (LSU) address/data pipelining to an Advanced Microcontroller Bus (AMB) interface (not shown), and address phase and writeback, data phase load, store, and branches.

The set of memory access circuitry 864 is coupled to the memory unit circuitry 870, which includes data TLB circuitry 872 coupled to data cache circuitry 874 coupled to level 2 (L2) cache circuitry 876. In one example, the memory access circuitry 864 may include load unit circuitry, a store address unit circuitry, and store data unit circuitry, each of which is coupled to the data TLB circuitry 872 in the memory unit circuitry 870. The instruction cache circuitry 834 is further coupled to the level 2 (L2) cache circuitry 876 in the memory unit circuitry 870. In one example, the instruction cache circuitry 834 and the data cache circuitry 874 are combined into a single instruction and data cache (not shown) in L2 cache circuitry 876, level 3 (L3) cache circuitry (not shown), and/or main memory. The L2 cache circuitry 876 is coupled to one or more other levels of cache and eventually to the main memory.

The core 890 may support one or more instructions sets (e.g., the x86 instruction set architecture (optionally with some extensions that have been added with newer versions); the MIPS instruction set architecture; the ARM instruction set architecture (optionally with optional additional extensions such as NEON)), including the instruction(s) described herein. In one example, the core 890 includes logic to support a packed data instruction set architecture extension (e.g., AVX1, AVX2), thereby allowing the operations used by many multimedia applications to be performed using packed data.

In some embodiments, the memory devices discussed in connection with FIGS. 5-8 can be configured (including tested) using the disclosed techniques (e.g., as discussed in connection with FIGS. 9-23).

In some embodiments, 3D CFETs can be used to improve transistor scaling where PMOS and NMOS transistors are vertically integrated into the same footprint, thereby achieving up to 50% area scaling in the area of CMOS logic gates (e.g., as illustrated in FIG. 9). On the other hand, conventional multi-ported RFs have an asymmetric number of PMOS and NMOS transistors which does not fit well in a balanced and grided diffusion pattern in CFET technology. For example, a traditional eight-transistor (8T) 1R1 W RF cell with one read port and one write port RF has 6 NMOS and 2 PMOS transistors. PMOS-to-NMOS ratio skews even further in traditional 10T 2R1 W with two read and one write ports, for a total of 8 NMOS and 2 PMOS transistors.

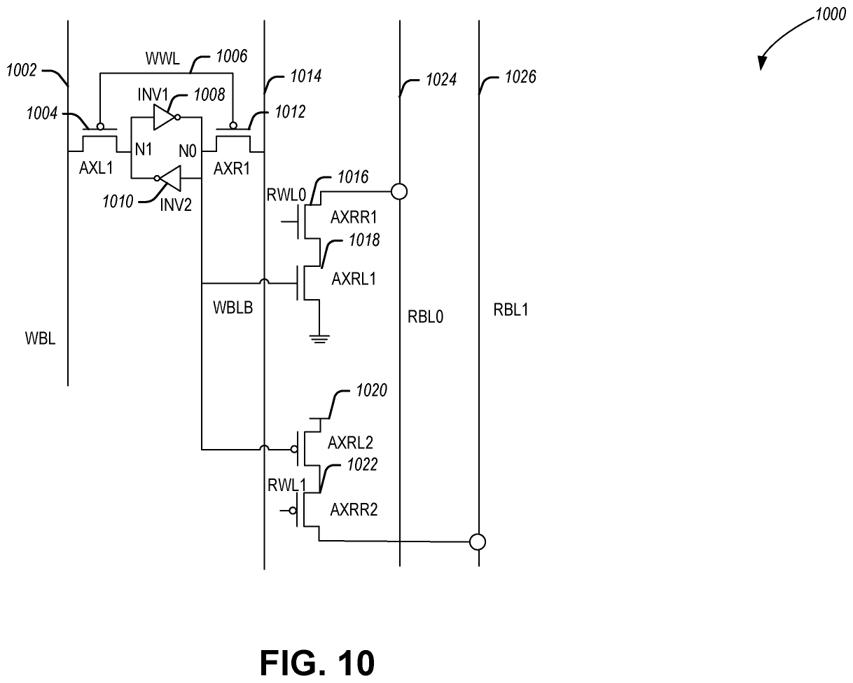

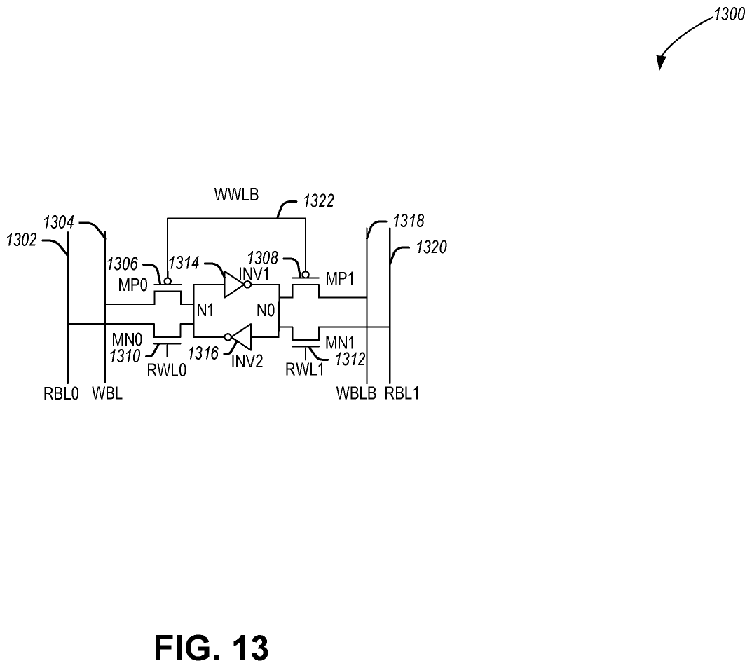

In some embodiments, a 10T 2R1 W design can be configured (e.g., as illustrated in FIGS. 10-12) which has a more balanced ratio of 6 PMOSs to 4 NMOSs transistors and is implemented in a layout that better exploits stacked transistors in a CFET process. Additionally, a fully-balanced 8T 2R1 W design with 4 NMOSs and 4 PMOSs is discussed in connection with FIGS. 13-21. More specifically, FIGS. 13-21 illustrate two efficient CFET-based layout topologies for the 8T 2R1 W cell, exploiting its lower as well as symmetric number of PMOS and NMOS transistors.

In this proposal, we provide two efficient layout topologies in the CFET process for implementing the 8T 2R1 W design in [REF4]. Layout topology 1 uses a 2 poly-pitch (PP) bitcell while layout topology 2 uses a 4PP bitcell, with the former enabling area saving of 25% and the latter enabling 38% area savings compared to the 10T 2R1 W bit-cell in the CFET process [REF3]. Different sets of vias using CFET technology are required to implement the 2PP bitcell (VGX, GCN, and BGCN) and 4PP bitcell (VGX and BVG) and so depending on the set of vias available in a given CFET process, one can choose between the two layouts.

In some embodiments, the disclosed 8T 2R1 W cell uses PMOS access transistors for the write port, which is the opposite of commonly used NMOS write ports. Furthermore, the use of assist techniques specific to PMOS write ports, such as Write bit line (BL) boosting or VSS collapse, indicates that a PMOS write transistor is used. In some aspects, an implementation of the 8T 2R1 W can be a split-gate implementation which results in PMOS and NMOS devices within the same stack having different gate connectivity.

In some embodiments, routing of read/write (Rd/Wr) BLs with backend metal resources are an indication that PMOS access transistors have been used. In the two poly-pitch (2PP) cell, the front Metal0 (M0) layer and the back side M0 (BM0) layer are fully utilized. In some aspects associated with four poly-pitch (4PP) cells, the front side Metal2 (M2) layer and back side Metal2 (BM2) are used in addition to M0 and M2 layers.

In some embodiments, the transistors in the discussed CFET stacks can be fully utilized with 4 NMOSs and 4 PMOSs.

FIG. 9 is a block diagram of a three-dimensional (3D) model of a CFET 900 with vertically stacked P-channel metal oxide semiconductor (PMOS) transistors and N-channel metal oxide semiconductor (NMOS) transistors, in accordance with some embodiments. The CFET 900 includes one or more PMOS transistors 906 formed over a substrate 902. The CFET 900 further includes one or more NMOS transistors 904 formed over the one or more PMOS transistors 906. In some embodiments, the one or more PMOS transistors 906 can be formed over or under the one or more NMOS transistors 904, but it is more common that the one or more PMOS transistors 906 are situated between the one or more NMOS transistors 904 and the substrate 902. The CFET 900 includes a reduced x-y area as compared to other transistor configurations, but at the expense of an increased height in the z-direction.

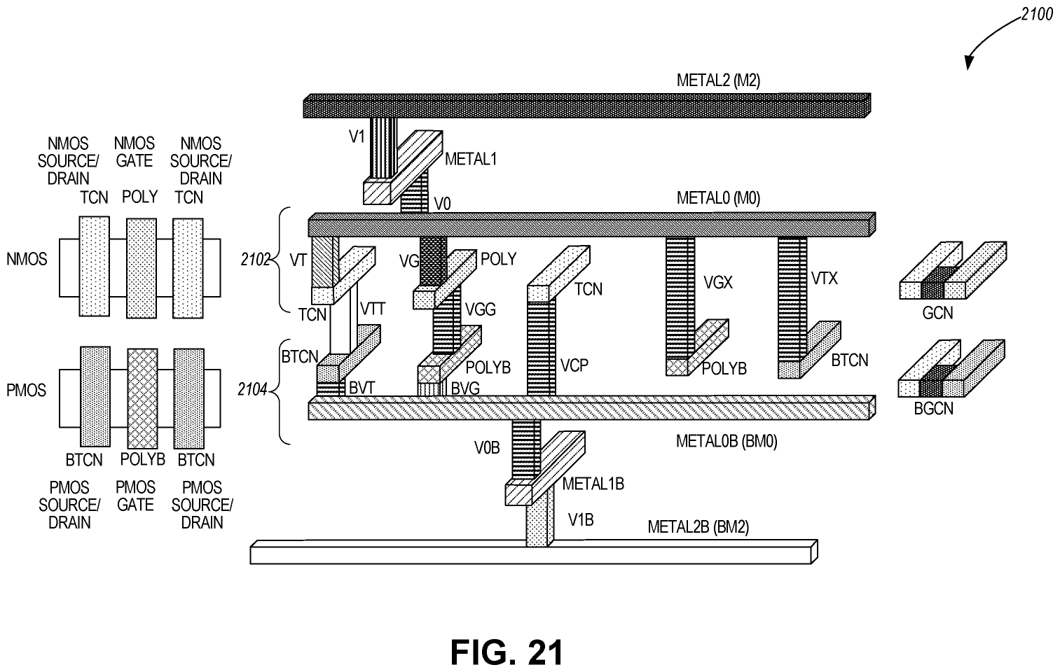

As used herein, the term “front side” refers to the front portion of a layout as viewed from the top (e.g., view in the direction A referenced in FIG. 9). In this regard, the “front side” in FIG. 9 refers to the layout including the layers of the one or more NMOS transistors 904. Another view of a layout front side is referenced as front side 2102 in FIG. 21 (e.g., disposed between the Metal0 (M0) layer and the back side 2104).

As used herein, the term “back side” refers to the back portion of a layout as viewed from the top and as disposed below the “front side” (e.g., view in the direction A referenced in FIG. 9 and disposed below the “front side”). In this regard, the “back side” in FIG. 9 refers to the layout including the layers of the one or more PMOS transistors 906. Another view of a layout back side is referenced as back side 2104 in FIG. 21 (e.g., disposed between the front side 2102 and the back side Metal 0 (BM0) layer).

FIG. 10 is a circuit diagram of an embodiment of a two-read-one-write (2R1 W) register file (RF) 1000 that benefits from CFET technology area gains, in accordance with some embodiments. Referring to FIG. 10, the 2R1 W RF 1000 includes a first write bit line (WBL) 1002, a second WBL (WBL bar or WBLB) 1014, a first read bit line (RBL0) 1024, and a second RBL (RBL1) 1026. The 2R1 W RF 1000 further includes inverters 1008 and 1010, PMOS transistors 1004, 1012, 1020, and 1022, and NMOS transistors 1016 and 1018. The gates of the PMOS transistors 1004 and 1012 are coupled to form a write word line (WWL) 1006.

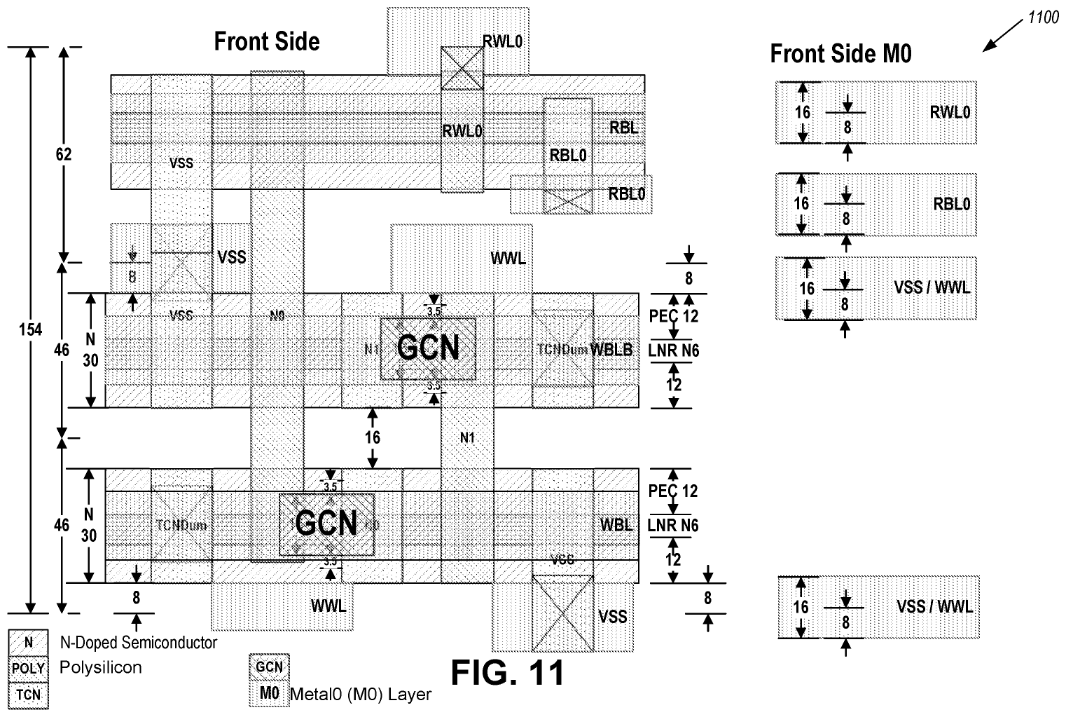

FIG. 11 is a layout diagram 1100 of an embodiment of a front side portion of the register file of FIG. 10, in accordance with some embodiments.

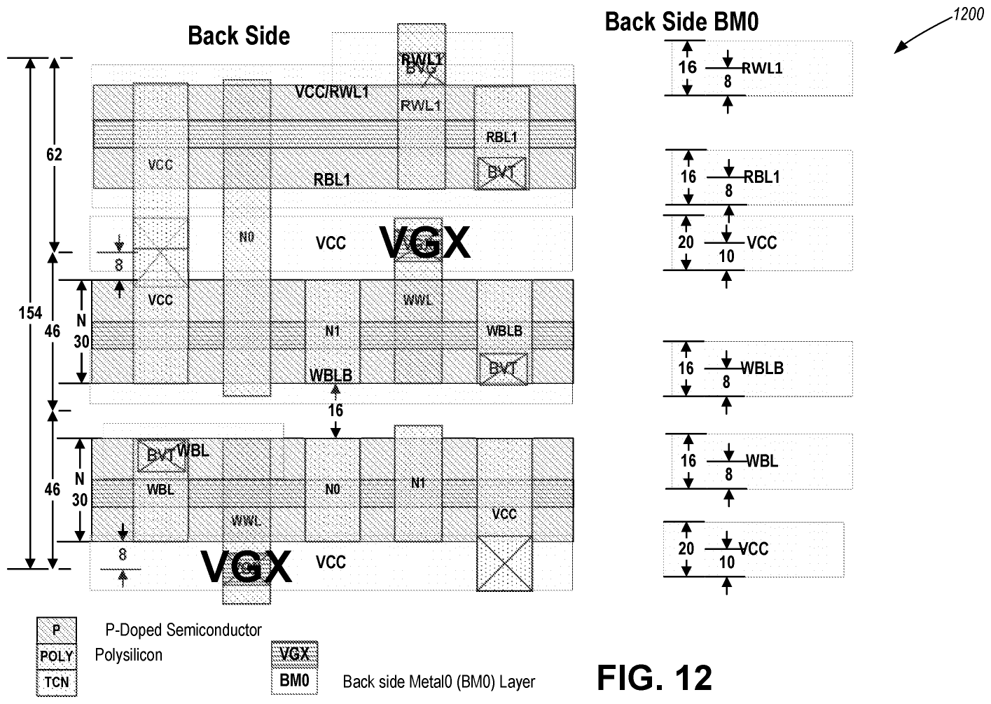

FIG. 12 is a layout diagram 1200 of an embodiment of a back side portion of the register file of FIG. 10, in accordance with some embodiments.

In the 10T 2R1 W RF 1000 in FIG. 10, using a PMOS write transistor along with complementary read ports with one read port based on NMOS devices, while the second read port based on PMOS devices, enables a design with 4 NMOS and 6 PMOS transistors which is more symmetric than that in the traditional 10T 2R1 W cell with NMOS-based read ports resulting in a cell with 8 NMOS and 2 PMOS transistors (not shown).

The register file layout in FIG. 11 and FIG. 12 performs the operations of the 2R1 W RF 1000 of FIG. 10. RF 1000 can be configured to enable more efficient utilization of a CFET stack, with the NMOS read port located on top of the PMOS port as shown in FIGS. 11-12. RF 1000 also maximizes utilization of the back side Metal 0 (BM0) layer resources as shown in FIG. 12. With the improved utilization, the cell height can be reduced by about 43% from 268 nm in a baseline design to 154 nm (as illustrated in FIGS. 11-12). Both the front side (FS) view (FIG. 11) and the back side (BS) view (FIG. 12) are shown with similar utilization for FS Metal0 (M0) and BS M0 (BM0) layers. The area saving of 43% versus traditional 10T 2R1 W cell (with NMOS-based read ports) is significant and it is closer to one technology generation advancement in memory density.

FIG. 13 is a circuit diagram of an embodiment of an eight-transistor (8T) 2R1 W register file (RF) 1300 with 4 NMOS and 4 PMOS transistors, in accordance with some embodiments. Referring to FIG. 13, the 2R1 W RF 1300 includes a first write bit line (WBL) 1304, a second WBL (WBL bar or WBLB) 1318, a first read bit line (RBL0) 1302, and a second RBL (RBL1) 1320. The 2R1 W RF 1300 further includes inverters 1314 and 1316, PMOS transistor 1306 (also referred to as MP0 or MP0 1306), PMOS transistor 1308 (also referred to as MP1 or MP1 1308), NMOS transistor 1310 (also referred to as MN0 or MN0 1310), and NMOS transistor 1312 (also referred to as MN1 or MN1 1312). The gates of the PMOS transistors 1306 and 1308 are coupled to form a write word line bar (WWLB) 1322. As illustrated in FIG. 13, the write port uses PMOS transistors MP0 and MP1, while read-port0 is enabled through MN0 and RBL0 1302 with read word line 0 (RWL0), and read-port1 is enabled through MN1 and RBL1 1320 with read word line 1 (RWL1).

Table 1 below shows a comparison of polarities of WBL, WBLB, write word line bar (WWLB), RBL0, RWL0, RWL1, and RWL1 between two CFET compatible 2R1 W designs (e.g., RF 1000 referenced as [REF3] and RF 1300 referenced as [REF4]) for write, read, and retention operations.

TABLE 1

| | | | | | | RBL1 | | RWL1 | |
|---|---|---|---|---|---|---|---|---|---|
| | WBL | WBLB | WWLB | RBL0 | RWL0 | [REF3] | [REF4] | [REF3] | [REF4] |
| Write 0 | VCC | 0 | 0 | VCC | 0 | 0 | VCC | VCC | 0 |
| Write 1 | 0 | VCC | 0 | VCC | 0 | 0 | VCC | VCC | 0 |
| BL0: Read 1 | VCC | VCC | VCC | 0 | VCC | 0 | VCC | VCC | 0 |
| BL0. Read 0 | VCC | VCC | VCC | VCC | VCC | 0 | VCC | VCC | 0 |
| BL1: Read 1 | VCC | VCC | VCC | VCC | 0 | 0 | 0 | 0 | VCC |
| BL1; Read 0 | VCC | VCC | VCC | VCC | 0 | VCC | VCC | 0 | VCC |
| Retention | VCC | VCC | VCC | VCC | 0 | 0 | VCC | VCC | 0 |

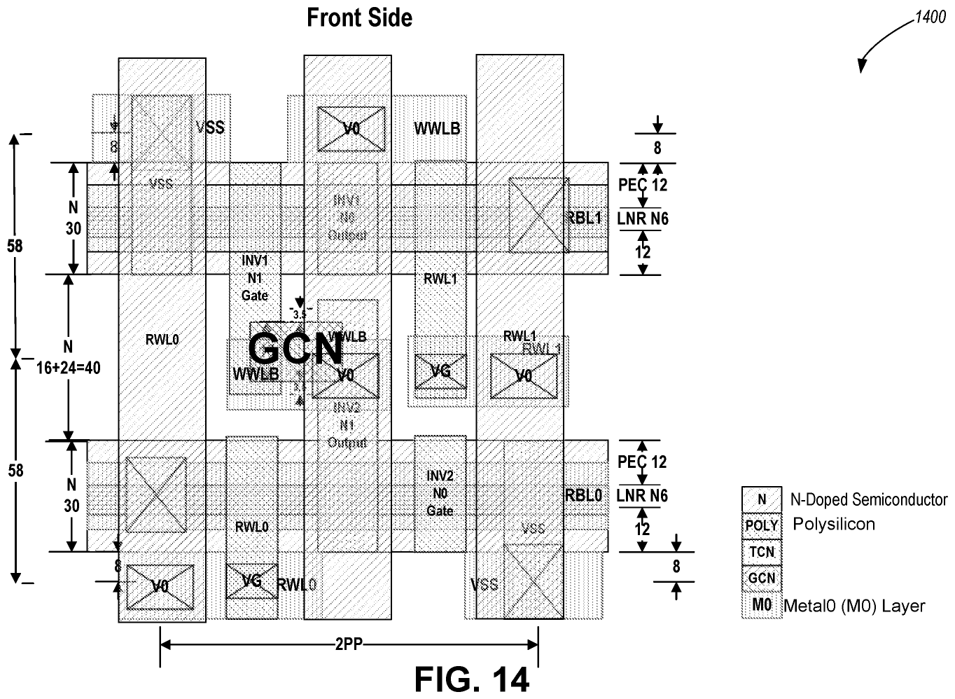

FIG. 14 is a layout diagram 1400 of an embodiment of a front side portion of the register file of FIG. 13, in accordance with some embodiments.

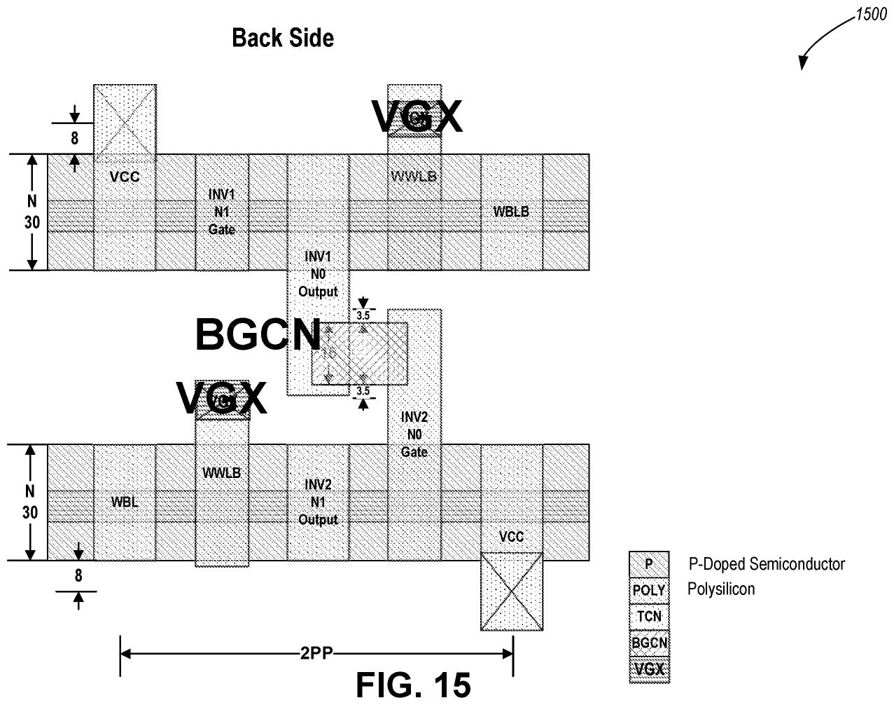

FIG. 15 is a layout diagram 1500 of an embodiment of a back side portion of the register file of FIG. 13, in accordance with some embodiments.

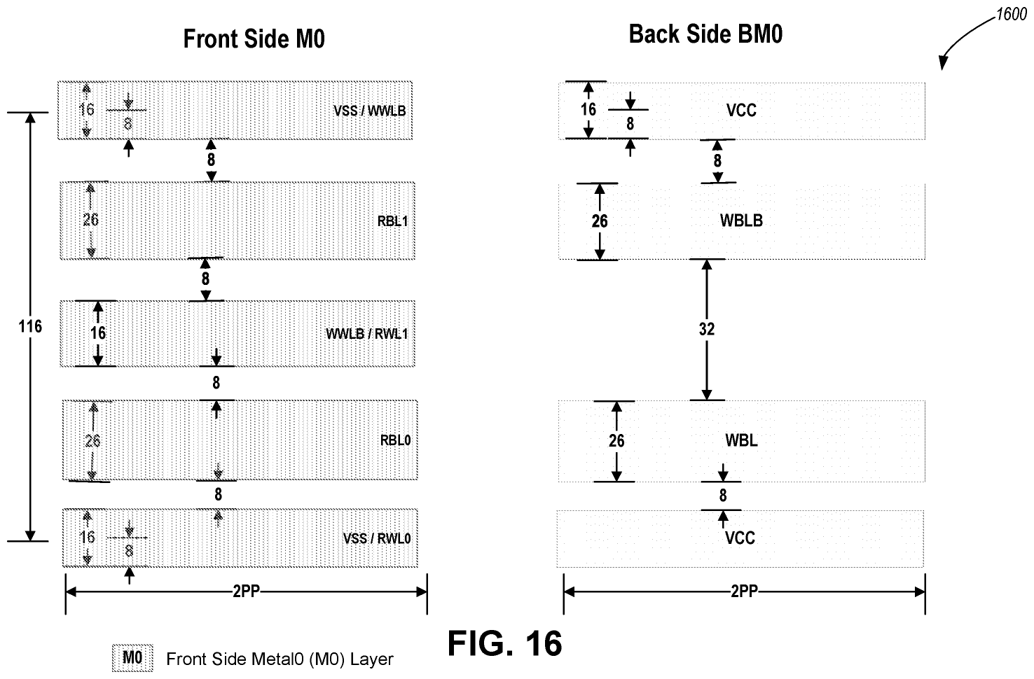

FIG. 16 is a layout diagram 1600 of an embodiment of a front side metal layer (e.g., M0) and a back side metal layer (e.g., BM0) of the register file of FIG. 13, in accordance with some embodiments.

In some embodiments, two different layout options can be used for implementing the 8T 2R1 W RF 1300 of FIG. 13. An example layout of layers and vias used by the disclosed register files is illustrated in FIG. 21. The description of FIG. 21 below further defines the different vias and layers used in the disclosed CFET layouts.

In the two-poly-pitch (2PP) version of RF 1300 shown in FIGS. 14-16, all 4 PMOS transistors are in the back side (BS) (e.g., back side 2104 in FIG. 21). Referring to FIGS. 14-16, the gates of write transistors MP0 and MP1 are connected to WWLB through a VGX via from backside poly (or gate) (POLYB) to front side M0 and then connected to M1 (in the center of the layout) through the V0 via. The write bit lines WBL and WBLB are routed through the back side M0 (BM0) layer, which is connected from the back side TCN (BTCN) through the BVT via (as discussed in connection with FIG. 21, tcn indicates NMOS source or drain, poly indicates NMOS gate, polyb indicates PMOS gate, and btcn indicates PMOS source or drain).

Read transistors MN0 and MN1 are activated by RWL0 and RWL1, respectively with RWL0 M1 routing done on the left side of the cell and RWL1 M1 routing done on the right side of the cell. The read word lines are connected to MN0 and MN1 through a VG via followed by M0, and then by a V0 via to the Metal 1 (M1) layer. The corresponding RBL0 and RBL1 are routed in the Metal0 (M0) layer. The cross-coupled N1 connection between INV2 output and INV1 gate is enabled through a front-side gate connection (GCN) via between front-side poly and front-side TCN. Another cross-coupled connection N0 between the INV2 gate and INV1 output is enabled through a back-side GCN (or BGCN), between back-side poly and BTCN.

The benefit of the proposed 2PP layout associated with FIGS. 14-16 is the highest metal layer used on the front side is M1 and the highest metal layer used on the back side is BM0 resulting in lower capacitance and hence higher performance for both read and write operations. Compared to the layout presented in FIGS. 11-12, the proposed layout improves the cell height area from 154 nm to 116 nm, giving 25% area savings. For the proposed 2PP layout associated with FIGS. 14-16, both front-side GCN (for N1 cross-coupled) and back-side BGCN (for NO cross-coupled) are used, whereas the layout in FIGS. 11-12 only uses a front side GCN. The list of vias required for the 2PP layout is given in Table 2 below.

Table 2 illustrates a comparison between the layout of 10T 2R1 W of FIG. 10 (referred to as [REF3]) and the proposed 2PP and 4PP layouts for 8T 2R1 W using CFET technology (e.g., associated with FIGS. 14-16 and FIGS. 17-20).

TABLE 2

| | | RBL0 | WBL | |
|---|---|---|---|---|
| | | and | and | Area |
| | Vias | RBL1 | WBLB | Normalized |
| 2R1W [REF3] | VGX, GCN | M0 and | BM0 | 1X |
| | | BM0 | | |
| Proposed 2PP 2R1W | VGX, GCN | M0 | BM0 | 0.75X |
| | and BGCN | | | |
| Proposed 4PP 2R1W | VGX, BVG | M2 | BM2 | 0.62X |

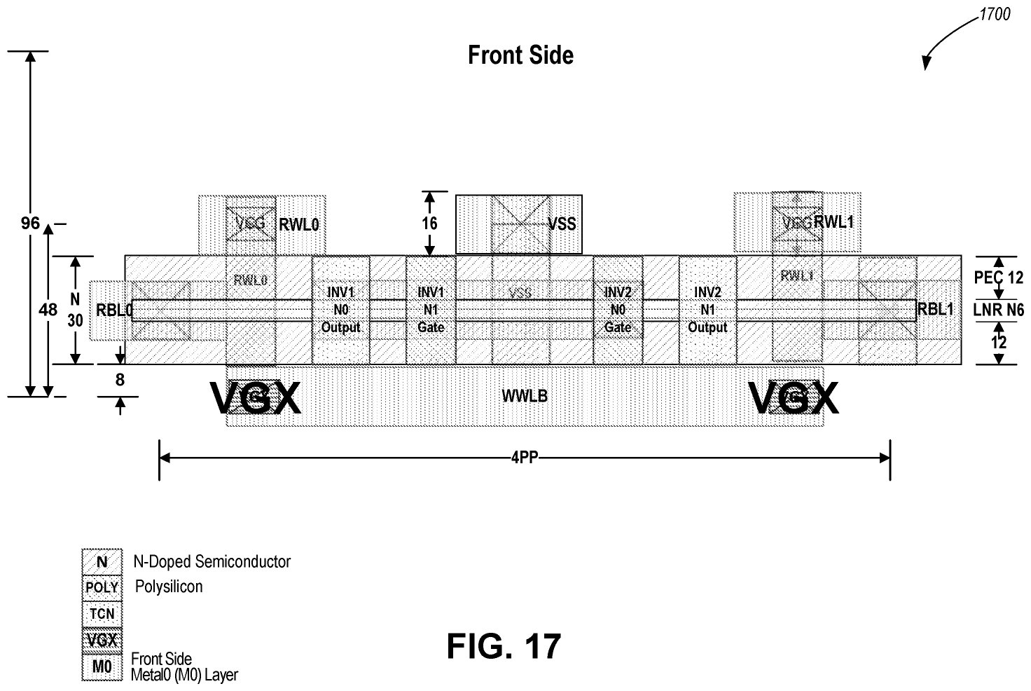

In some embodiments, a four-poly-pitch (4PP) version of the layout of RF 1300 is illustrated in FIGS. 17-20.

FIG. 17 is a layout diagram 1700 of an embodiment of a front side portion of the register file of FIG. 13, in accordance with some embodiments.

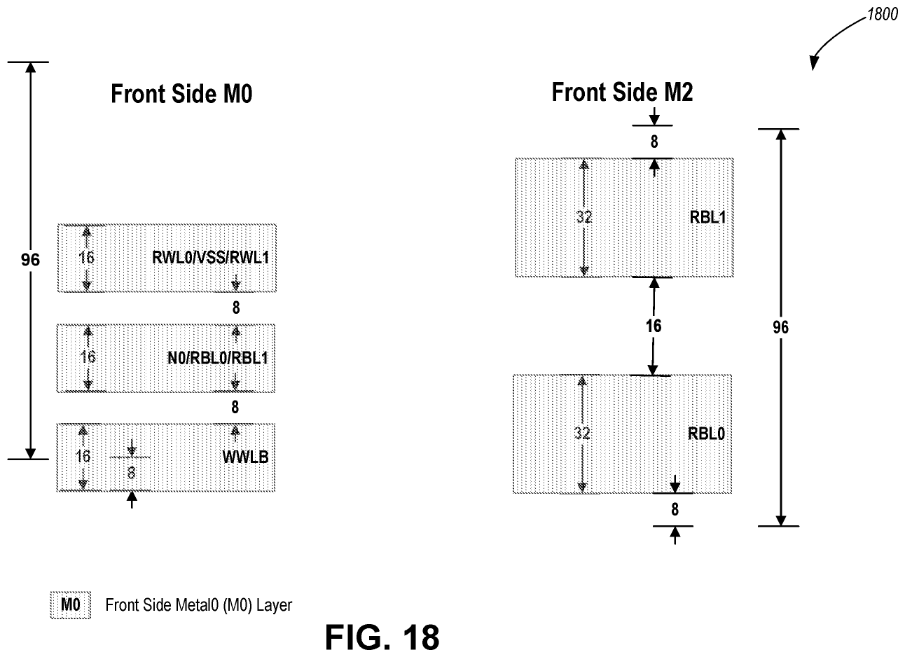

FIG. 18 is a layout diagram 1800 of an embodiment of front side metal layers of the register file of FIG. 13, in accordance with some embodiments.

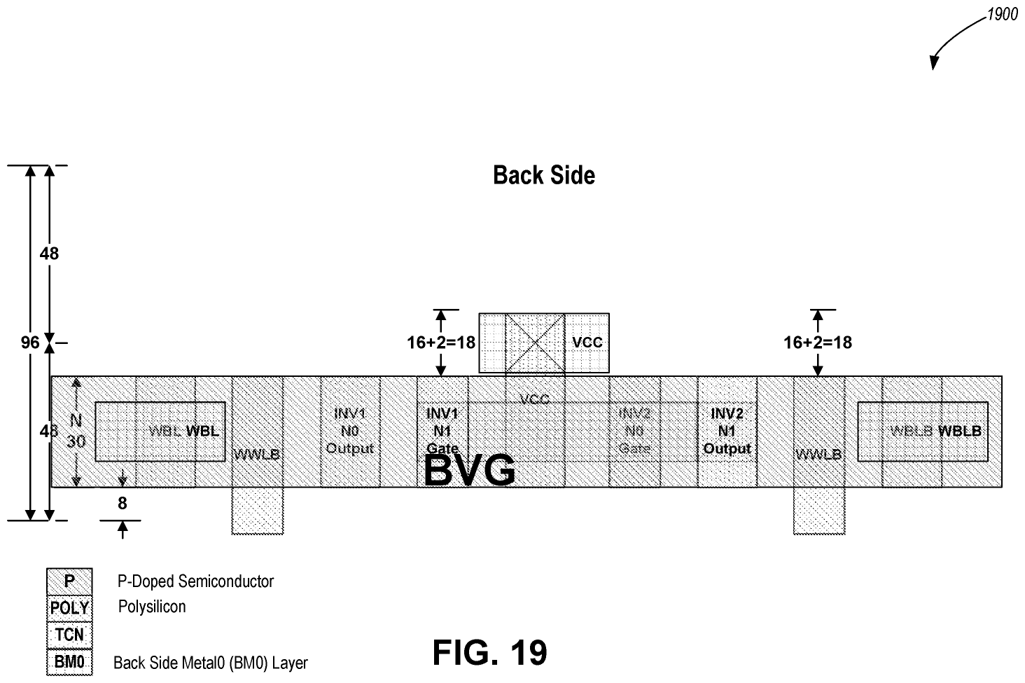

FIG. 19 is a layout diagram 1900 of an embodiment of a back side portion of the register file of FIG. 13, in accordance with some embodiments.

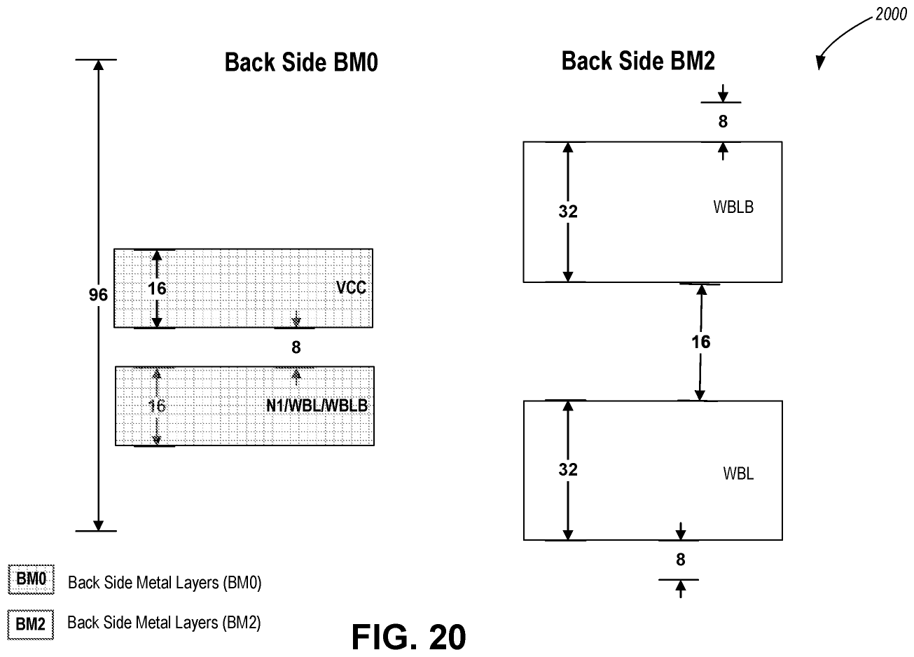

FIG. 20 is a layout diagram 2000 of an embodiment of back side metal layers of the register file of FIG. 13, in accordance with some embodiments.

Unlike the layouts in FIGS. 11-12 and FIGS. 14-16, the proposed layouts associated with FIGS. 17-20 do not require a front side GCN or a back side GCN (BGCN). Instead of the cross-coupled connection N1, the proposed layout associated with FIGS. 17-20 configures BVG via to connect the back side POLYB to the back side BM0 (e.g., FIG. 17) and also configures VG via to connect the front side poly to the front side M0 for the N0 connection (e.g., FIG. 19). Due to the additional use of BM0 and M0 for the cross-coupled connections N0 and N1, the proposed layout associated with FIGS. 17-20 configures tapping into M2 for routing RBL0 and RBL1 (e.g., FIG. 18) and back side BM2 for WBL and WBLB connections (e.g., FIG. 18). Due to the additional metal usage, the BL capacitance for both read and operation increases, which can degrade read and write performance versus the 2PP design. On the other hand, 4PP layout optimization results in a net area reduction of 154 nm×2PP (of the 10T 2R1 W cell shown in FIG. 10 and referenced as [REF3]) to 48 nm×4PP giving 37.6% area savings. The savings is 12.6% larger than the 2PP layout associated with FIGS. 14-16 with the help of the BVG via.

FIG. 21 is a reference layout 2100 of layers and vias used by the disclosed CFET devices, in accordance with some embodiments. The following is a list of definitions associated with corresponding layers and vias illustrated in FIG. 21:
(a) VG: Indicates a connection between the NMOS poly/gate to the M0 layer;
(b) BVG: Indicates a connection between the PMOS poly/gate to the BM0 layer;
(c) VGG: Indicates a connection between the NMOS poly/gate to the PMOS poly/gate;
(d) VT: Indicates a connection between the NMOS source/drain to the M0 layer;
(e) BVT: Indicates a connection between the PMOS source/drain to the BM0 layer;
(f) VTT: Indicates a connection between the NMOS source/drain to the PMOS source/drain;
(g) TCN: Indicates a connection to the NMOS source/drain diffusion;
(h) BTCN: Indicates a connection to the PMOS source/drain diffusion;
(i) VGX: Indicates a connection between the PMOS poly/gate to the M0 layer;
(j) VTX: Indicates a connection between the PMOS source/drain to the M0 layer;
(k) VCP: Indicates a connection between the NMOS source/drain to the BM0 layer;
(l) GCN: Indicates a connection between the NMOS poly/gate to the NMOS source/drain;
(m) BGCN: Indicates a connection between the PMOS poly/gate to the PMOS source/drain;
(n) V0: Indicates a connection between the Metal0 (M0) and Metal 1 (M1) layers;
(o) V1: Indicates a connection between the M1 and Metal2 (M2) layers;
(p) V0B: Indicates a connection between the Metal0B (BM0) and Metal1B (BM1) layers; and
(q) V1B: Indicates a connection between the M1B and Metal2B (BM2) layers.

In some embodiments, one or more of the metal layers in FIG. 21 (e.g., BM2) can be formed over a substrate (e.g., a semiconductor substrate such as substrate 902 in FIG. 9).

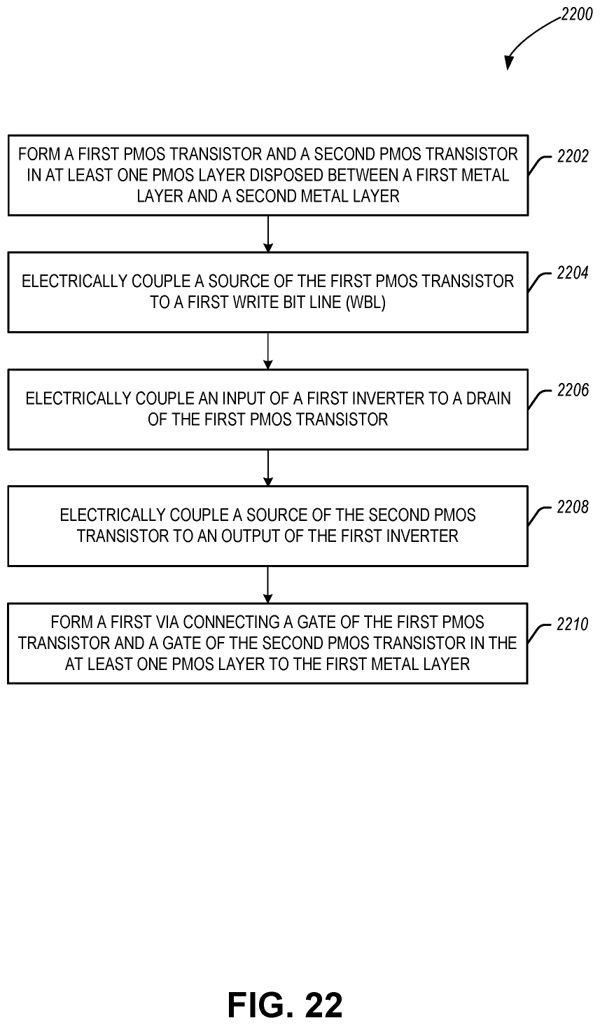

FIG. 22 is a flow diagram of an example method 2200 for configuring a register file, in accordance with some embodiments. Referring to FIG. 22, method 2200 includes operations 2202, 2204, 2206, 2208, and 2210, which may be executed by a memory configuration circuit or another processor of a computing device (e.g., hardware processor 2302 of machine 2300 illustrated in FIG. 23).

At operation 2202, a first P-channel metal oxide semiconductor (PMOS) transistor (e.g., MP0) and a second PMOS transistor (MP1) are formed in at least one PMOS layer. The at least one PMOS layer is disposed between a first metal layer (e.g., a Metal0 (M0) layer) and a second metal layer (e.g., a Metal0b (BM0) layer) (e.g., as illustrated in FIG. 21).

At operation 2204, a source of the first PMOS transistor (MP0) is electrically coupled to a first write bit line (WBL) (e.g., WBL 1304).

At operation 2206, an input of a first inverter (e.g., INV1 1314) is electrically coupled to a drain of the first PMOS transistor (MP0).

At operation 2208, a source of the second PMOS transistor (e.g., MP1) is electrically coupled to an output of the first inverter (e.g., INV1 1314).

At operation 2210, a first via is formed (e.g., via VGX in FIG. 15). The first via connects a gate of the first PMOS transistor and a gate of the second PMOS transistor in the at least one PMOS layer to the first metal layer.

FIG. 23 illustrates a block diagram of an example machine 2300 upon which any one or more of the techniques (e.g., methodologies) discussed herein may perform. In alternative embodiments, the machine 2300 may operate as a standalone device or may be connected (e.g., networked) to other machines. In a networked deployment, machine 2300 may operate in the capacity of a server machine, a client machine, or both in server-client network environments. In an example, machine 2300 may act as a peer machine in a peer-to-peer (P2P) (or other distributed) network environment. The machine 2300 may be a personal computer (PC), a tablet PC, a set-top box (STB), a personal digital assistant (PDA), a portable communications device, a mobile telephone, a smartphone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine (e.g., computer system) 2300 may include a hardware processor 2302 (e.g., a central processing unit (CPU), a graphics processing unit (GPU), a hardware processor core, or any combination thereof), a main memory 2304, and a static memory 2306, some or all of which may communicate with each other via an interlink (e.g., bus) 2308. In some aspects, the main memory 2304, the static memory 2306, or any other type of memory (including cache memory) used by the machine 2300 can be configured based on the disclosed techniques or can implement the disclosed memory devices.

Specific examples of main memory 2304 include Random Access Memory (RAM), and semiconductor memory devices, which may include, in some embodiments, storage locations in semiconductors such as registers. Specific examples of static memory 2306 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 2300 may further include a display device 2310, an input device 2312 (e.g., a keyboard), and a user interface (UI) navigation device 2314 (e.g., a mouse). In an example, the display device 2310, input device 2312, and UI navigation device 2314 may be a touchscreen display. The machine 2300 may additionally include a storage device (e.g., drive unit or another mass storage device) 2316, a signal generation device 2318 (e.g., a speaker), a network interface device 2320, and one or more sensors 2321, such as a global positioning system (GPS) sensor, compass, accelerometer, or other sensors. The machine 2300 may include an output controller 2328, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the processor 2302 and/or instructions 2324 may comprise processing circuitry and/or transceiver circuitry.

The storage device 2316 may include a machine-readable medium 2322 on which is stored one or more sets of data structures or instructions 2324 (e.g., software) embodying or utilized by any one or more of the techniques or functions described herein. The instructions 2324 may also reside, completely or at least partially, within the main memory 2304, within static memory 2306, or the hardware processor 2302 during execution thereof by machine 2300. In an example, one or any combination of the hardware processor 2302, the main memory 2304, the static memory 2306, or the storage device 2316 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 2322 is illustrated as a single medium, the term “machine-readable medium” may include a single medium or multiple media (e.g., a centralized or distributed database, and/or associated caches and servers) configured to store one or more instructions 2324.

An apparatus of the machine 2300 may be one or more of a hardware processor 2302 (e.g., a central processing unit (CPU), a graphics processing unit (GPU), a hardware processor core, or any combination thereof), a main memory 2304 and a static memory 2306, one or more sensors 2321, a network interface device 2320, antennas 2360, a display device 2310, an input device 2312, a UI navigation device 2314, a storage device 2316, instructions 2324, a signal generation device 2318, and an output controller 2328. The apparatus may be configured to perform one or more of the methods and/or operations disclosed herein. The apparatus may be intended as a component of machine 2300 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by the machine 2300 and that causes the machine 2300 to perform any one or more of the techniques of the present disclosure, or that is capable of storing, encoding or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 2324 may further be transmitted or received over a communications network 2326 using a transmission medium via the network interface device 2320 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 2320 may include one or more physical jacks (e.g., Ethernet, coaxial, or phone jacks) or one or more antennas to connect to the communications network 2326. In an example, the network interface device 2320 may include one or more antennas 2360 to wirelessly communicate using at least one single-input multiple-output (SIMO), multiple-input multiple-output (MIMO), or multiple-input single-output (MISO) techniques. In some examples, the network interface device 2320 may wirelessly communicate using Multiple User MIMO techniques. The term “transmission medium” shall be taken to include any intangible medium that is capable of storing, encoding, or carrying instructions for execution by the machine 2300, and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a certain manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at different times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments such as part of a wireless local area network (WLAN), 3rd Generation Partnership Project (3GPP) Universal Terrestrial Radio Access Network (UTRAN), or Long-Term-Evolution (LTE) or a Long-Term-Evolution (LTE) communication system, although the scope of the disclosure is not limited in this respect.

Antennas referred to herein may comprise one or more directional or omnidirectional antennas, including, for example, dipole antennas, monopole antennas, patch antennas, loop antennas, microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, antennas may be effectively separated to take advantage of spatial diversity and the different channel characteristics that may result between each antenna and the antennas of a transmitting station. In some MIMO embodiments, antennas may be separated by up to 1/10 of a wavelength or more.

Described implementations of the subject matter can include one or more features, alone or in combination as illustrated below by way of examples.

Example 1 is an apparatus comprising: a first write bit line (WBL); a first P-channel metal oxide semiconductor (PMOS) transistor including a source coupled to the WBL; a first inverter including an input coupled to a drain of the first PMOS transistor; a second PMOS transistor including a source coupled to an output of the first inverter, the first PMOS transistor and the second PMOS transistor disposed in at least one PMOS layer configured between a first metal layer and a second metal layer; and a first via connecting a gate of the first PMOS transistor and a gate of the second PMOS transistor in the at least one PMOS layer to the first metal layer.

In Example 2, the subject matter of Example 1 includes the first metal layer is a Metal0 (M0) layer, the second metal layer is a Metal0b (BM0) layer, and the apparatus further comprises a second via connecting the M0 layer to a Metal1 (M1) layer.

In Example 3, the subject matter of Example 2 includes, a second WBL (WBLB) coupled to a drain of the second PMOS transistor; and a third via connecting the WBL and the WBLB to the BM0 layer.

In Example 4, the subject matter of Examples 1-3 includes a first read bit line (RBL); a first N-channel metal oxide semiconductor (NMOS) transistor including a source coupled to the first RBL; and a second inverter including an output coupled to a drain of the first NMOS transistor.

In Example 5, the subject matter of Example 4 includes, a second RBL; and a second NMOS transistor including a drain coupled to the second RBL, the first NMOS transistor, and the second NMOS transistor disposed in at least one NMOS layer configured between the first metal layer and the PMOS layer.

In Example 6, the subject matter of Example 5 includes subject matter where the first inverter comprises a third NMOS transistor and a third PMOS transistor, and the second inverter comprises a fourth NMOS transistor and a fourth PMOS transistor.

In Example 7, the subject matter of Example 6 includes, a second via connecting a gate of the third NMOS transistor to a drain of the fourth NMOS transistor.

In Example 8, the subject matter of Example 7 includes, a third via connecting a drain of the third PMOS transistor to a gate of the fourth PMOS transistor.

Example 9 is a memory device comprising: a plurality of interfaces forming one or more bit lines; and a plurality of register files communicatively coupled via at least one of the plurality of interfaces, wherein a register file of the plurality of register files comprises: a first write bit line (WBL) of the one or more bit lines; a first P-channel metal oxide semiconductor (PMOS) transistor including a source coupled to the WBL; a first inverter including an input coupled to a drain of the first PMOS transistor; a second PMOS transistor including a source coupled to an output of the first inverter, the first PMOS transistor and the second PMOS transistor disposed in at least one PMOS layer configured between a Metal0 (M0) layer and a Metal0b (BM0) layer; and a first via connecting a gate of the first PMOS transistor and a gate of the second PMOS transistor in the at least one PMOS layer to the M0 layer.

In Example 10, the subject matter of Example 9 includes subject matter where the memory device is a static random access memory (SRAM).

In Example 11, the subject matter of Examples 9-10 includes subject matter where the register file further comprises: a second via connecting the M0 layer to a Metal1 (M1) layer.

In Example 12, the subject matter of Example 11 includes subject matter where the register file further comprises: a second WBL (WBLB) coupled to a drain of the second PMOS transistor; and a third via connecting the WBL and the WBLB to the BM0 layer.

In Example 13, the subject matter of Examples 9-12 includes subject matter where the register file further comprises: a first read bit line (RBL) of the one or more bit lines; a first N-channel metal oxide semiconductor (NMOS) transistor including a source coupled to the first RBL; and a second inverter including an output coupled to a drain of the first NMOS transistor.

In Example 14, the subject matter of Example 13 includes subject matter where the register file further comprises: a second RBL; and a second NMOS transistor including a drain coupled to the second RBL, the first NMOS transistor, and the second NMOS transistor disposed in at least one NMOS layer configured between the M0 layer and the PMOS layer.

In Example 15, the subject matter of Example 14 includes subject matter where the first inverter comprises a third NMOS transistor and a third PMOS transistor, and the second inverter comprises a fourth NMOS transistor and a fourth PMOS transistor.

In Example 16, the subject matter of Example 15 includes subject matter where the register file further comprises: a second via connecting a gate of the third NMOS transistor to a drain of the fourth NMOS transistor.

In Example 17, the subject matter of Example 16 includes subject matter where the register file further comprises: a third via connecting a drain of the third PMOS transistor to a gate of the fourth PMOS transistor.

Example 18 is a method for configuring a register file, the method comprising: forming a first P-channel metal oxide semiconductor (PMOS) transistor and a second PMOS transistor in at least one PMOS layer, the at least one PMOS layer disposed between a first metal layer and a second metal layer; electrically coupling a source of the first PMOS transistor to a first write bit line (WBL); electrically coupling an input of a first inverter to a drain of the first PMOS transistor; electrically coupling a source of the second PMOS transistor to an output of the first inverter, and forming a first via connecting a gate of the first PMOS transistor and a gate of the second PMOS transistor in the at least one PMOS layer to the first metal layer.

In Example 19, the subject matter of Example 18 includes the first metal layer is a Metal0 (M0) layer, the second metal layer is a Metal0b (BM0) layer, and the method further comprises forming a second via connecting the M0 layer to a Metal1 (M1) layer; electrically coupling a drain of the second PMOS transistor to a second WBL (WBLB); and forming a third via connecting the WBL and the WBLB to the BM0 layer.

In Example 20, the subject matter of Examples 18-19 includes, electrically coupling a source of a first N-channel metal oxide semiconductor (NMOS) transistor to a first read bit line (RBL); electrically coupling a drain of the first NMOS transistor to an output of a second inverter; electrically coupling a drain of a second NMOS transistor to a second RBL, the first NMOS transistor and the second NMOS transistor disposed in at least one NMOS layer configured between the first metal layer and the PMOS layer; forming a second via connecting a gate of a third NMOS transistor of the first inverter to a drain of a fourth NMOS transistor of the second inverter; and forming a third via connecting a drain of a third PMOS transistor of the first inverter to a gate of a fourth PMOS transistor of the second inverter.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a first write bit line (WBL);
a first P-channel metal oxide semiconductor (PMOS) transistor including a source coupled to the WBL;
a first inverter including an input coupled to a drain of the first PMOS transistor;
a second PMOS transistor including a source coupled to an output of the first inverter, the first PMOS transistor and the second PMOS transistor disposed in at least one PMOS layer configured between a first metal layer and a second metal layer; and
a first via connecting a gate of the first PMOS transistor and a gate of the second PMOS transistor in the at least one PMOS layer to the first metal layer.

2. The apparatus of claim 1, wherein the first metal layer is a Metal0 (M0) layer, the second metal layer is a Metal0b (BM0) layer, and the apparatus further comprising:
a second via connecting the M0 layer to a Metal1 (M1) layer.

3. The apparatus of claim 2, further comprising:
a second WBL (WBLB) coupled to a drain of the second PMOS transistor; and
a third via connecting the WBL and the WBLB to the BM0 layer.

4. The apparatus of claim 1, further comprising:
a first read bit line (RBL);
a first N-channel metal oxide semiconductor (NMOS) transistor including a source coupled to the first RBL; and
a second inverter including an output coupled to a drain of the first NMOS transistor.

5. The apparatus of claim 4, further comprising:
a second RBL; and
a second NMOS transistor including a drain coupled to the second RBL, the first NMOS transistor and the second NMOS transistor disposed in at least one NMOS layer configured between the first metal layer and the PMOS layer.

6. The apparatus of claim 5, wherein the first inverter comprises a third NMOS transistor and a third PMOS transistor, and the second inverter comprises a fourth NMOS transistor and a fourth PMOS transistor.

7. The apparatus of claim 6, further comprising:
a second via connecting a gate of the third NMOS transistor to a drain of the fourth NMOS transistor.

8. The apparatus of claim 7, further comprising:
a third via connecting a drain of the third PMOS transistor to a gate of the fourth PMOS transistor.

9. A memory device comprising:
a plurality of interfaces forming one or more bit lines; and
a plurality of register files communicatively coupled via at least one of the plurality of interfaces, wherein a register file of the plurality of register files comprises:
a first write bit line (WBL) of the one or more bit lines;
a first P-channel metal oxide semiconductor (PMOS) transistor including a source coupled to the WBL;
a first inverter including an input coupled to a drain of the first PMOS transistor;
a second PMOS transistor including a source coupled to an output of the first inverter, the first PMOS transistor and the second PMOS transistor disposed in at least one PMOS layer configured between a Metal0 (M0) layer and a Metal0b (BM0) layer; and
a first via connecting a gate of the first PMOS transistor and a gate of the second PMOS transistor in the at least one PMOS layer to the M0 layer.

10. The memory device of claim 9, wherein the memory device is a static random access memory (SRAM).

11. The memory device of claim 9, wherein the register file further comprises:
a second via connecting the M0 layer to a Metal1 (M1) layer.

12. The memory device of claim 11, wherein the register file further comprises:
a second WBL (WBLB) coupled to a drain of the second PMOS transistor; and
a third via connecting the WBL and the WBLB to the BM0 layer.

13. The memory device of claim 9, wherein the register file further comprises:
a first read bit line (RBL) of the one or more bit lines;
a first N-channel metal oxide semiconductor (NMOS) transistor including a source coupled to the first RBL; and
a second inverter including an output coupled to a drain of the first NMOS transistor.

14. The memory device of claim 13, wherein the register file further comprises:
a second RBL; and
a second NMOS transistor including a drain coupled to the second RBL, the first NMOS transistor and the second NMOS transistor disposed in at least one NMOS layer configured between the M0 layer and the PMOS layer.

15. The memory device of claim 14, wherein the first inverter comprises a third NMOS transistor and a third PMOS transistor, and the second inverter comprises a fourth NMOS transistor and a fourth PMOS transistor.

16. The memory device of claim 15, wherein the register file further comprises:
a second via connecting a gate of the third NMOS transistor to a drain of the fourth NMOS transistor.

17. The memory device of claim 16, wherein the register file further comprises:
a third via connecting a drain of the third PMOS transistor to a gate of the fourth PMOS transistor.

18. A method for configuring a register file, the method comprising:
forming a first P-channel metal oxide semiconductor (PMOS) transistor and a second PMOS transistor in at least one PMOS layer, the at least one PMOS layer disposed between a first metal layer and a second metal layer;
electrically coupling a source of the first PMOS transistor to a first write bit line (WBL);
electrically coupling an input of a first inverter to a drain of the first PMOS transistor;
electrically coupling a source of the second PMOS transistor to an output of the first inverter, and
forming a first via connecting a gate of the first PMOS transistor and a gate of the second PMOS transistor in the at least one PMOS layer to the first metal layer.

19. The method of claim 18, wherein the first metal layer is a Metal0 (M0) layer, the second metal layer is a Metal0b (BM0) layer, and the method further comprising:
forming a second via connecting the M0 layer to a Metal1 (M1) layer;
electrically coupling a drain of the second PMOS transistor to a second WBL (WBLB); and
forming a third via connecting the WBL and the WBLB to the BM0 layer.

20. The method of claim 18, further comprising:
electrically coupling a source of a first N-channel metal oxide semiconductor (NMOS) transistor to a first read bit line (RBL);
electrically coupling a drain of the first NMOS transistor to an output of a second inverter;
electrically coupling a drain of a second NMOS transistor to a second RBL, the first NMOS transistor and the second NMOS transistor disposed in at least one NMOS layer configured between the first metal layer and the PMOS layer,
forming a second via connecting a gate of a third NMOS transistor of the first inverter to a drain of a fourth NMOS transistor of the second inverter; and
forming a third via connecting a drain of a third PMOS transistor of the first inverter to a gate of a fourth PMOS transistor of the second inverter.
